(19) United States
(12) Patent Application Publication
(10) Pub. No.: US 2007/0103204 A1
(43) Pub. Date: May 10, 2007

(54) Method and apparatus for conversion between quasi differential signaling and true differential signaling

(75) Inventors: Kenneth W. Egan, Austin, TX (US); Stephen J. Sheafor, Boulder, CO (US); Gregory T. Chandler, Austin, TX (US); Geoffrey E. Brehmer, Lexington, TX (US)

Correspondence Address: LARSON NEWMAN ABEL POLANSKY & WHITE, LLP, 5914 WEST COURTYARD DRIVE, SUITE 200, AUSTIN, TX, 78730, US

(73) Assignee: X-EMI, Inc., Austin, TX (US)

(21) Appl. No.: 11/518,862

(22) Filed: Sep. 11, 2006

Related U.S. Application Data
(60) Provisional application No. 60/736,111, filed on Nov. 10, 2005.
(60) Provisional application No. 60/810,980, filed on Jun. 5, 2006.

(51) Int. Cl. H03K 5/01

(52) U.S. Cl. 327/100

(57) ABSTRACT

Transmit-side active signal management circuitry applies one or more active signal management processes to a digital signal at a transmit side of an interconnect. At the receive side of the interconnect, receive-side active signal management circuitry applies one or more corresponding active signal management processes, as appropriate, to the received digital signal to recover the information represented by the original digital signal. The interconnect can include a cable used to transmit the signals between a source device and a destination device, whereby one or both of the transmit-side active signal management circuitry and the receive-side active signal management circuitry is implemented at a corresponding cable receptacle of the cable. Alternately, one or both of the transmit-side active signal management circuitry and the receive-side active signal management circuitry can be implemented at a cable adaptor, thereby permitting the use of a passive cable interconnect to transmit the signal.

### CROSS-REFERENCE TO RELATED APPLICATIONS

The present application claims priority to U.S. patent application Ser. No. 60/736,111 (Attorney Docket No. 1009-0009-P) filed Nov. 10, 2005 and entitled “System and Method of EMI Reduction in Digital Video Interfaces,” the entirety of which is incorporated by reference herein. The present application also claims priority to U.S. patent application Ser. No. 60/810,980 (Attorney Docket No. 1009-0009-P2) filed Jun. 6, 2006 and entitled “System and Method for Reduction of EMI in Cables and Other Interconnects,” the entirety of which is incorporated by reference herein.

The present application is related to the following applications, the entireties of which are incorporated by reference herein: U.S. patent application Ser. No. ______(Attorney Docket No. 1009-0016), filed on even date herewith and entitled “Active Signal Management in Cables and Other Interconnects”; U.S. patent application Ser. No. ______(Attorney Docket No. 1009-0017), filed on even date herewith and entitled “Bidirectional Active Signal Management in Cables and Other Interconnects”; U.S. patent application Ser. No. ______(Attorney Docket No. 1009-0018), filed on even date herewith and entitled “Encoding and Deserialization-Reserialization in Digital Signals”; and U.S. patent application Ser. No. ______(Attorney Docket No. 1009-0020), filed on even date herewith and entitled “Skew Management in Cables and Other Interconnects”.

### BACKGROUND

1. Field of the Invention

The present disclosure relates generally to the communication of digital signals via interconnects, and more particularly to active signal management of digital signals transmitted via interconnects.

2. Description of the Related Art

The proper operation of a digital device typically is dependent on reliable transitions in data signals and clock signals. However, as device speeds increase, the analog effects exhibited by a digital signal due to device features can cause substantial distortion in the transmitted digital signal, thereby decreasing the reliability and reach of the transmitted digital signal. Device features that frequently contribute to signal distortion can include, for example, circuit layout, P channel and N channel transistor mismatches, parasitic resistances and capacitances, transmission length mismatches, and the like. Further, ring noise and the emission of electromagnetic interference (EMI) by the interconnect during the transmission of the signal can result in a degradation of the signal.

Interconnects are a particular source of signal degradation and electromagnetic interference (EMI) due to their particular physical and operational characteristics, such as relatively long signal transmission lengths, paired interconnect length mismatches, and lack of substantial shielding. In an attempt provide signal management (e.g., an attempt to reduce signal degradation and emitted EMI), some transmitting devices connected at the transmit end of an interconnect utilize circuitry to improve the signal quality characteristics of the signal prior to its transmission via the interconnect, and some transmission devices connected at the receive end of an interconnect can utilize circuitry to more reliably recover the transmitted signal upon its reception via the interconnect. It will be appreciated that the source device and the destination device may not be specifically tailored to communicate with each other. To illustrate, the source device may be from a different manufacturer or from a different product line than the destination device and the source device and destination device may implement different processes for improving signal quality, if any at all. Accordingly, if the process applied by the circuitry of the transmitting device is incompatible with the recovery process applied by the circuitry of the receiving device, or vice versa, some or all of the circuitry of the transmitting device and/or the receiving device may need to be disabled to permit compatibility between the transmitting device and the receiving device. By disabling the functionality of the circuitry, however, the signal quality and EMI reduction benefits provided by the circuitry of the devices are diminished or eliminated. Further, in the event that it is not feasible to disable the circuitry of a transmitting device or a receiving device, one or both of the devices may be inoperable with the other, thereby preventing their joint integration. A device manufacturer or device provider therefore often is faced with a choice between utilizing circuitry at the device for improving signal quality thereby running the risk of rendering the device incompatible with other devices, or eliminating or severely limiting the use of any such circuitry, thereby increasing the likelihood of signal distortion and increased emitted EMI. Accordingly, an improved technique for signal management of signals transmitted via interconnects would be advantageous.

### BRIEF DESCRIPTION OF THE DRAWINGS

The present disclosure may be better understood, and its numerous objects, features, and advantages made apparent to those skilled in the art by referencing the accompanying drawings. The use of the same reference symbols in different drawings indicates similar or identical items.

FIG. 1 is a block diagram illustrating a signal management system for improving transmitted signal quality and reach and reducing electromagnetic interference (EMI) in accordance with at least one embodiment of the present disclosure.

FIG. 2 is a diagram illustrating the signal management system of FIG. 1 implemented in a cable in accordance with at least one embodiment of the present disclosure.

FIG. 3 is a perspective view diagram illustrating a cable receptacle of the cable assembly of FIG. 2 in accordance with at least one embodiment of the present disclosure.

FIG. 4 is a diagram illustrating the signal management system of FIG. 1 as implemented in a cable adaptor in accordance with at least one embodiment of the present disclosure.

FIG. 5 is a perspective view diagram illustrating the cable adaptor of FIG. 4 in accordance with at least one embodiment of the present disclosure.

FIG. 6 is a block diagram illustrating an implementation of active signal management circuitry utilizing quasi differential to true differential signal conversion in accordance with at least one embodiment of the present disclosure.

FIG. 7 is a block diagram illustrating an implementation of active signal management circuitry utilizing quasi differential to true differential signal conversion in accordance with at least one embodiment of the present disclosure.

FIG. 8 is a block diagram illustrating an implementation of active signal management circuitry utilizing encoding and quasi differential to true differential signal conversion in accordance with at least one embodiment of the present disclosure.

FIG. 9 is a block diagram illustrating an implementation of active signal management circuitry utilizing true differential to quasi differential signal conversion and decoding in accordance with at least one embodiment of the present disclosure.

FIG. 10 is a block diagram illustrating an implementation of active signal management circuitry utilizing deserialization-serialization and encoding in accordance with at least one embodiment of the present disclosure.

FIG. 11 is a block diagram illustrating an implementation of active signal management circuitry utilizing deserialization-serialization and decoding in accordance with at least one embodiment of the present disclosure.

FIG. 12 is a block diagram illustrating an implementation of active signal management circuitry utilizing a quasi differential receiver and transmitter in accordance with at least one embodiment of the present disclosure.

FIG. 13 is a block diagram illustrating an implementation of active signal management circuitry utilizing a true differential receiver and transmitter in accordance with at least one embodiment of the present disclosure.

FIG. 14 is a circuit diagram illustrating an implementation of a quasi differential signal transmitter in accordance with at least one embodiment of the present disclosure.

FIG. 15 is a circuit diagram illustrating an implementation of a true differential signal transmitter in accordance with at least one embodiment of the present disclosure.

FIG. 16 is a circuit diagram illustrating an implementation of a quasi differential signal receiver in accordance with at least one embodiment of the present disclosure.

FIG. 17 is a circuit diagram illustrating an implementation of a true differential signal receiver in accordance with at least one embodiment of the present disclosure.

FIG. 18 is a circuit diagram illustrating an implementation of a quasi-to-true differential signaling converter in accordance with at least one embodiment of the present disclosure.

FIG. 19 is a circuit diagram illustrating an implementation of a true-to-quasi differential signaling converter in accordance with at least one embodiment of the present disclosure.

FIG. 20 is a diagram illustrating a bidirectional active signal management system employed at respective ends of a cable assembly in accordance with at least one embodiment of the present disclosure.

FIG. 21 is a diagram illustrating an alternate implementation of a bidirectional active signal management system employed at respective ends of a cable assembly in accordance with at least one embodiment of the present disclosure.

FIG. 22 is a diagram illustrating a direction detection module in accordance with at least one embodiment of the present disclosure.

FIG. 23 is a diagram illustrating an implementation of a signal processing path of a bidirectional active signal management system in accordance with at least one embodiment of the present disclosure.

FIG. 24 is a diagram illustrating another implementation of a signal processing path of a bidirectional active signal management system in accordance with at least one embodiment of the present disclosure.

FIG. 25 is a block diagram illustrating an implementation of active signal management circuitry utilizing a bit alignment module in accordance with at least one embodiment of the present disclosure.

FIG. 26 is a block diagram illustrating an implementation of active signal management circuitry utilizing a skew management module in accordance with at least one embodiment of the present disclosure.

FIG. 27 is a block diagram illustrating an implementation of active signal management circuitry utilizing a control symbol encoder/decoder in accordance with at least one embodiment of the present disclosure.

FIG. 28 is a block diagram illustrating an implementation of an EMI encoder/decoder in accordance with at least one embodiment of the present disclosure.

FIG. 29 is a block diagram illustrating an implementation of an EMI encoder/decoder in accordance with at least one embodiment of the present disclosure.

FIG. 30 is a block diagram illustrating an implementation of an EMI encoder/decoder in accordance with at least one embodiment of the present disclosure.

FIG. 31 is a block diagram illustrating an implementation of an EMI encoder/decoder in accordance with at least one embodiment of the present disclosure.

FIG. 32 is a block diagram illustrating an implementation of an EMI encoder/decoder in accordance with at least one embodiment of the present disclosure.

FIG. 33 is a block diagram illustrating an implementation of an EMI encoder/decoder in accordance with at least one embodiment of the present disclosure.

FIG. 34 is a block diagram illustrating an implementation of an EMI encoder/decoder in accordance with at least one embodiment of the present disclosure.

FIG. 35 is a block diagram illustrating an implementation of an EMI encoder/decoder in accordance with at least one embodiment of the present disclosure.

FIG. 36 is a block diagram illustrating an implementation of an EMI encoder/decoder in accordance with at least one embodiment of the present disclosure.

FIG. 37 is a block diagram illustrating an implementation of an EMI encoder/decoder in accordance with at least one embodiment of the present disclosure.

FIG. 38 is a block diagram illustrating an implementation of an EMI encoder/decoder in accordance with at least one embodiment of the present disclosure.

FIG. 39 is a block diagram illustrating an implementation of an EMI encoder/decoder in accordance with at least one embodiment of the present disclosure.

FIG. 40 is a state machine diagram illustrating an operation of an EMI encoder/decoder in accordance with at least one embodiment of the present disclosure.

### DETAILED DESCRIPTION OF THE PREFERRED EMBODIMENTS

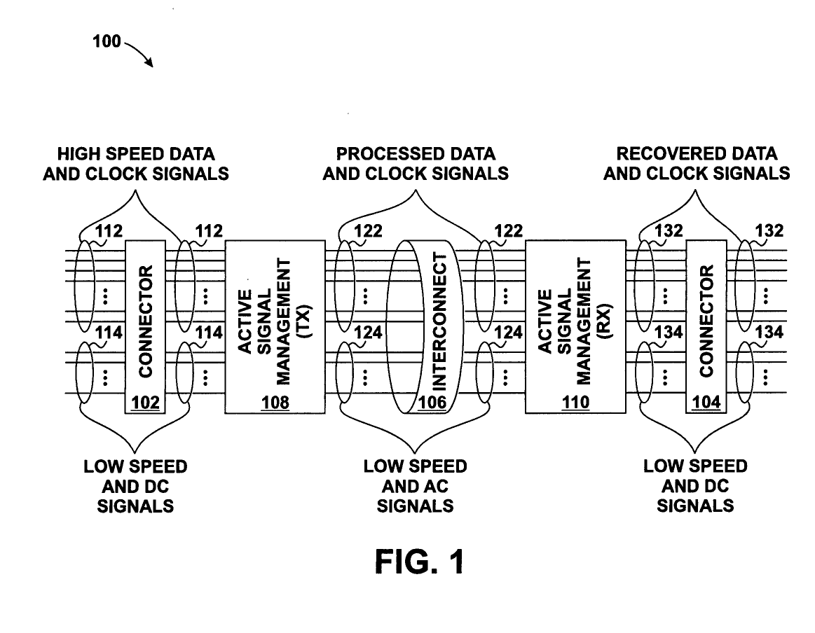

FIGS. 1-40 illustrate active signal management techniques for improving the quality or fidelity of a digital signal transmitted via an interconnect. In at least one embodiment, transmit-side active signal management circuitry applies one or more signal management processes to a digital signal at a transmit side of the interconnect. At the receive side of the interconnect, receive-side active signal management circuitry applies one or more corresponding active signal management processes, as appropriate, to the received digital signal to recover the information represented by the original digital signal. In one embodiment, the interconnect comprises a cable used to transmit the signals between a source device and a destination device, whereby one or both of the transmit-side active signal management circuitry and the receive-side active signal management circuitry is implemented at a corresponding cable receptacle of the cable. In another embodiment, one or both of the transmit-side active signal management circuitry and the receive-side active signal management circuitry is implemented at a cable adaptor, thereby permitting the use of a conventional passive cable interconnect to transmit the signal between a source device and a destination device. In an alternate embodiment, the transmit-side active signal management circuitry is integrated at the source device and the receive-side active signal management circuitry is integrated at the destination device, thereby facilitating the transmission of the processed signal via a conventional passive cable interconnect or other interconnect.

The term “active signal management circuitry” and its variants, as used herein, is defined as circuitry implementing one or more transistor devices configured to manipulate a digital signal. The term “active signal management process” and its variants, as used herein, is defined as a manipulation of a digital signal using active signal management circuitry. The term “symbol,” as used herein, refers either to one or more particular data values (such as the bit sequence used to identify a HSYNC or VSYNC control symbol in DVI) or a sequence of bit values having an identified length (e.g., an 8-bit byte, a 16-bit symbol, a 32-bit double symbol, etc.), depending on context.

The term “cable,” as used herein, is defined as an assembly of two or more conductive interconnects in an enveloping sheath and at least one cable receptacle disposed at a corresponding end of the sheath and electrically coupled to at least a subset of the two or more conductive interconnects. The term “cable adaptor,” as used herein, is defined as an assembly of a housing and at least two electrically coupled cable receptacles disposed at the housing. The term “cable receptacle,” as used herein, is defined as a receptacle configured to removably electrically couple and removably mechanically couple with a cable interface of a device or with another cable receptacle. The term “cable assembly,” as used herein, refers to either a cable or a cable adaptor.

The term “active cable,” as used herein, is defined as a cable implementing active signal management circuitry. The term “active cable adaptor,” as used herein, is defined as a cable adaptor implementing active signal management circuitry. The term “passive cable,” as used herein, is defined as a cable that does not implement active signal management circuitry. The term “passive cable adaptor” as used herein, is defined as a cable adaptor that does not implement active signal management circuitry. Unless otherwise noted, a passive cable coupled to at least one active cable adaptor is considered an active cable for the purposes of the present disclosure.

The term “quasi differential signaling” and its variants, as used herein, is defined as differential signaling comprising a pair of differential signal components (a true component and a complement component) whereby a current return path for one of the differential signal components of the pair is not provided or substantially inhibited on the other differential signal component of the pair. Quasi differential signaling techniques are in essence merely complementary pair signaling techniques. Examples of quasi differential signaling include, but not limited to, Current Mode Logic (CML), which provides current sink only with near or far end termination, Pseudo Emitter Coupled Logic (PECL), Low Voltage Emitter Coupled Logic (LVECL), High Speed Current Steering Logic (HCSL), which is the inverse of CML with current sources with either near or far end termination. In contrast, the term “true differential signaling” and its variants, as used herein, is defined as differential signaling comprising a pair of differential signal components (a true component and a complement component) whereby a current return path for each of the differential signal components of substantially uninhibited on the other differential signal component of the pair. Examples of true differential signaling include, but are not limited to Low Voltage Differential Signaling (LVDS), differential signaling in accordance with the Electronic Industry (EIA) 644-A or EIA-899 standards, and the like.

For ease of illustration, the techniques disclosed herein are described in the context of the transmission of high-definition television (HDTV) related signals, and more specifically, the transmission of signaling based on the digital video interface (DVI) and the high-definition multimedia interface (HDMI) standards. However, it will be appreciated that these techniques can be employed in other high speed signaling environments without departing from the scope of the present disclosure. Examples of other signal transmission formats in which the disclosed techniques can be implemented include, but are not limited to, the Video Electronics Standards Association (VESA) DisplayPort standard, the Unified Display Interface (UDI) standard, the Serial Attached Small Computer System Interface (SAS) standard, the Universal Serial Bus (USB) standard (e.g., USB 1.0 or USB 2.0), the Institute of Electronic and Electrical Engineers (IEEE) 1394 standard (also known as the Firewire standard), the Peripheral Component Interconnect Express (PCI-Express) standard, packetized networking standards, and the like.

Referring to FIG. 1, a signal management system 100 for improving the fidelity of quality of digital signals transmitted via a cable assembly or other interconnect is illustrated in accordance with at least one embodiment of the present disclosure. The signal management system 100 includes a transmit-side connector 102, receive-side connector 104, an interconnect assembly 106, active signal management transmit circuitry 108, and active signal management receive circuitry 110. The transmit-side connector 102 is associated with a source device (not shown), such as, for example, a digital versatile disc (DVD) player, high-definition television (HDTV) set-top box, an audio/video receivers, a video game console, an audio/video switch, a distribution amplifier, and the like. The receive-side connector 104 is associated with a destination device, such as, for example, a television, video projector, and the like.

The transmit-side connector 102 provides high-speed data/clock signals 112 and low-speed data/DC signals 114 from the source device to the active signal management transmit circuitry 108. Due to the potential for signal distortion and/or relatively high EMI, the active signal management transmit circuitry 108 applies one or more active signal management processes to the high-speed data/clock signals 112 to generate processed data/clock signals 122, which are provided to the interconnect assembly 106 for transmission. In certain instances, the potential for distortion of the low-speed/DC signals 114 or the EMI emitted by the low-speed/DC signals 114 may be within acceptable parameters due to the low frequency of these signals. The low-speed/DC signals 114 therefore can be passed-through to the interconnect assembly 106 as low-speed/DC signals 124 without active signal management processing. In other instances, some or all of the low-speed/DC signals 114 can be processed by the active signal management transmit circuitry 108 to reduce the potential for signal distortion and or emitted EMI.

At the receive end, the active signal management receive circuitry 110 receives the reduced-EMI data/clock signals 122 and the low-speed/DC signals 124 via the interconnect 126. The active signal management receive circuitry 110 applies one or more active signal management processes, such as active signal management processes, to the processed data/clock signals 122 to generate corresponding recovered high-speed data/clock signals 132 that are representative of the high-speed data/clock signals 112 provided for transmission at the transmit end. The recovered high-speed data/clock signals 132 then are provided to the destination device via the receive-end connector 104 for processing.

The one or more active signal management processes applied at the active signal management transmit circuitry 108, and consequently the active signal management recovery processes applied at the active signal management receive circuitry 110, are based on the characteristics of the high-speed data/clock signals, their means of transmission and reception, and the data that they represent. As will be appreciated, quasi differential signaling techniques often exhibit significant EMI due to the presence of a common mode current and skew between twisted pair wires, whereas true differential signaling techniques often exhibit less EMI by comparison. Accordingly, in one embodiment, one active signal management process that can be employed at the transmit side includes the conversion of a quasi differential signal to a true differential signal for transmission via the interconnect assembly 106. However, the destination device may be configured to only handle the specified type of quasi differential signaling. Accordingly, the corresponding active signal management process employed at the receive side to recover the original digital signal can include the conversion of the transmitted true differential signal to a quasi differential signal at the receive end. To illustrate, the DVI and HDMI standards specify the use of current mode logic (CML)-based differential signaling, which is a type of quasi differential signaling. Accordingly, an active signal management process to reduce signal degradation during transmission can include the conversion of the CML-based data/clock signals to a true differential signal format, such as a low voltage differential signaling (LVDS) format. Further, passive equalization can be used to mitigate cable loss and to reduce EMI.

Another active signal management process can include the encoding of a periodic or quasi periodic digital signal, such as a high-speed clock signal, with a random or pseudo-random noise source so as to reduce the effective periodicity of the signal, and thereby reducing the emitted EMI of the transmitted signal. Conversely, the corresponding active signal management process to recover the original periodic or quasi periodic digital signal can include decoding the encoded signal using a synchronized noise source to recover the original periodic or quasi periodic signal. To illustrate, the DVI and HDMI standards specify the transmission of a pixel clock, which is a high frequency periodic signal. Accordingly, the pixel clock can be encoded by the active signal management transmit circuitry 108 to generate an encoded pixel clock signal and the encoded pixel clock signal can be decoded at the active signal management receive circuitry 110 to recover the original pixel clock signal.

Further, certain high-speed data signals may be have a periodic data symbol or other component that results in significant EMI emission. To illustrate, the DVI and HDMI standards specify the inclusion of control (CTL) symbols (e.g., a horizontal sync (HSYNC) and a vertical synch (VSYNC) symbol) into a data signal on a periodic basis. Because these CTL symbols appear at a fixed frequency in the data signal, they can introduce significant emitted EMI. As another example, a video data symbol representative of video information may be periodically transmitted at a certain frequency, thereby introducing EMI in relation to that frequency. Accordingly, in one embodiment, an active signal management process can include the identification and encoding of substantially periodic data symbols in an otherwise non-periodic data stream so as to generate a symbol-encoded data stream with reduced EMI. At the receive end, the corresponding active signal management process to recover the original data signal can include the identification and decoding of encoded periodic data symbols in the symbol-encoded data stream to recover the original data signal.

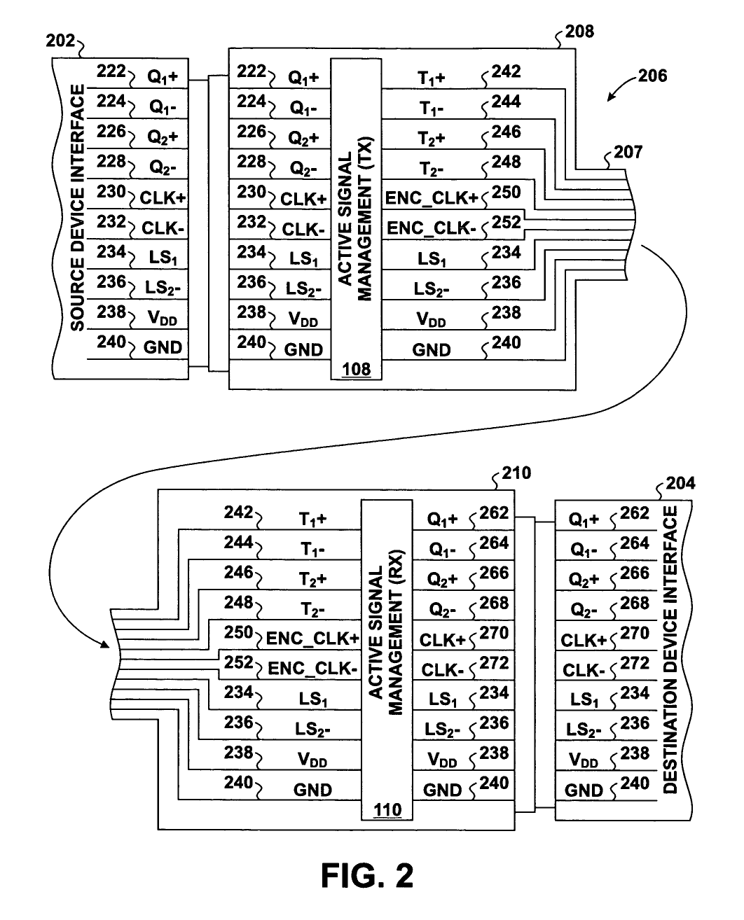

Referring to FIG. 2, an implementation of an active signal management system in a cable assembly is illustrated in accordance with at least one embodiment of the present disclosure. In the depicted example, a source device interface 202 and a destination device interface 204 are connected via a cable 206. For ease of illustration, the cable 206 is described in the context of a DVI/HDMI cable. The cable 206 includes a cable receptacle 208 configured to electrically and mechanically connect to the source device interface 202 and a cable receptacle 210 configured to electrically and mechanically connect to the destination device interface 210, whereby the cable receptacle 208 and the cable receptacle 210 are electrically connected via conductive interconnects of a cable body 207. Disposed at the cable receptacle 208 is the active signal management transmit circuitry 108 and disposed at the cable receptacle 210 is the active signal management receive circuitry 110. The active signal management transmit circuitry 108 and the active signal management receive circuitry 110 can be implemented as one or more integrated circuits, such as, for example, an application specific integrated circuit (ASIC) or programmable logic (e.g., a field programmable gate array or FPGA). In one embodiment, the cable body 207 can include, for example, several instances of twisted pairs enveloped in a shield of mylar or aluminum foil with a drain wire, in which the aggregate body of twisted pairs are grouped and embedded in a jacket which is covered with a coaxial shield, which can include copper, aluminum, nickel, steel or other conducting materials. In other embodiments, the cable body 207 can include one or more twin-axial (twinax) cable bodies, or unshielded twisted pairs (UTP).

For ease of illustration, the high-speed data/clock signals provided by the source device for transmission via the cable 206 include a first quasi differential data signal represented by signal Q₁⁺ and its complement signal Q₁⁻ (signals 222 and 224, respectively), a second quasi differential data signal represented by signal Q₂⁺ and its complement signal Q₂⁻ (signals 226 and 228, respectively), and a quasi differential clock signal represented by signal CLK⁺ and its complement signal CLK⁻ (signals 230 and 232, respectively). Likewise, for ease of illustration, the low-speed data/DC signals provided for transmission by the source device include a low speed signal LS₁, (signal 234), a low speed signal LS₂ (signal 236), a voltage reference signal V_{DD} (signal 238) and a voltage reference signal GND (signal 240). Although this particular combination of digital signals is illustrated for ease of discussion, it will be appreciated that the techniques described herein can be utilized for any number or signaling-type of digital signals using the guidelines provided herein.

In the depicted example, the active signal management transmit circuitry 108 at the cable receptacle 208 associated with the transmit side performs one or more active signal management processes on the first quasi differential data signal (signals Q₁⁺ and Q₁⁻) to generate a first processed data signal represented by signals T₁⁺ and T₁⁻ (signals 242 and 244, respectively). The active signal management transmit circuitry 108 also performs one or more active signal management processes on the second quasi differential data signal (signals Q₂⁺ and Q₂⁻) to generate a second processed data signal represented by signals T₂⁺ and T₂⁻ (signals 246 and 248, respectively). The active signal management transmit circuitry 108 likewise performs one or more active signal management processes on the quasi differential clock signal (represented by signals CLK⁺ and CLK⁻) to generate a processed clock signal represented by signals ENC_CLK⁺ and ENC_CLK⁻ (signals 250 and 252, respectively). In the illustrated example, the low speed signals LS₁, and LS₂ and the voltage reference signals V_{DD} and GND either bypass the active signal management transmit circuitry 108 or receive minimal or no processing by the active signal management transmit circuitry 108 due to their relatively low potential for distortion or emitted EMI.

The resulting processed signals are transmitted from the cable receptacle 208 to the cable receptacle 210 via the cable body 207, whereupon they are processed by the active signal management receive circuitry 110 to recover the signals originally provided by the source device via the source device interface 202. The active signal management receive circuitry 110 performs one or more active signal management processes on the received first processed data signal (signals T₁⁺ and T₁⁻) to generate a first recovered quasi differential data signal represented by recovered signals Q₁⁺ and Q₁⁻ (signals 262 and 264, respectively) which represent the original signals Q₁⁺ and Q₁⁻ provided by the source device interface 202. The active signal management receive circuitry 110 also performs one or more active signal management processes on the received second processed data signal (signals T₁⁺ and T₁⁻) to generate a second recovered quasi differential data signal represented by recovered signals Q₂³⁰ and Q₂⁻ (signals 266 and 268, respectively) which represent the original signals Q₂⁺ and Q₂⁻ provided by the source device interface 202. Likewise, the active signal management receive circuitry 110 also performs one or more active signal management processes on the received processed clock signal (signals ENC_CLK⁺ and ENC_CLK⁻) to generate a recovered quasi differential clock signal represented by recovered signals CLK⁺ and CLK⁻ (signals 270 and 272, respectively) which represent the original signals CLK⁺ and CLK⁻ provided by the source device interface 202. In the illustrated embodiment, the low speed signals LS₁, and LS₂ and the voltage reference signals V_{DD} and GND receive minimal or no processing before being provided to the destination device interface 204 because they were minimally processed, if at all, at the transmit end. The recovered signals are provided to the destination device via the destination device interface 204 for subsequent processing (e.g., processing for display).

In one embodiment, the active signal management transmit circuitry 108 and the active signal management transmit circuitry 110 are powered by the voltage reference signals transmitted via the cable interconnect 208, such as the voltage reference signals V_{DD} and GND. However, in certain instances, the source device interface 202 may be unable to source sufficient current or voltage to adequately power the active signal management transmit circuitry 108 and the active signal management receive circuitry 110. In this instance, the cable 206 can include a power interface (not shown) to receive adequate power. The power interface can include, for example, a USB interface, a voltage interface to an ADC converter that connects to a standard 115 VAC wall outlet, and the like.

As noted above with respect to FIG. 1, the one or more active signal management processes performed by the active signal management transmit circuitry 108 on a digital signal can include, but are not limited to, quasi-to-true differential signaling conversion, signal encoding using a noise source, skew management, passive equalization, clock encoding, encryption (e.g., using a data encryption standard (DES), pretty good privacy (PGP) encryption process, elliptical curve algorithms, hash tables or other entropy management or diffusion techniques as appropriate), deserialization and reserialization, periodic symbol encoding, and combinations thereof. The corresponding active signal management process at the receive end so as to recover the original digital signal therefore can include true-to-quasi differential signaling conversion, signal decoding, clock decoding, periodic symbol decoding, skew alignment, decryption, and combinations thereof.

The implementation of active signal management circuitry at one or both of the cable receptacles 208 and 210 of the cable 206 provides a number of advantages. In many instances, it may be infeasible to implement the active signal management circuitry at the source device or the destination device due to cost considerations or compatibility issues. Accordingly, the implementation of the active signal management circuitry within the cable 206 itself allows the cable 206 to be compatible with both the source device and the destination device while still providing for improve signal fidelity for digital signals transmitted via the cable 206. In other instances, active signal management circuitry may be implemented at one of the source device and the destination device, but not the other. In this case, the implementation of the corresponding active signal management at the other end of the cable 206 can permit or otherwise facilitate the use of the active signal management process.

To illustrate, assume that the source device employs active signal management circuitry at its cable interface while the destination device does not have active signal management circuitry at its cable interface. If the source device were to apply an active signal management process that materially alters the transmitted signal, such as the encoding or encryption of the digital signal, the destination device, lacking active signal management circuitry, would be unable to recover the original signal from the altered signal, which would result in an incompatibility between the source device and the destination device or result in the disabling of the active signal management circuitry at the source device. However, if the source device and the destination device were connected using a cable assembly having the active signal management receive circuitry 110 at the cable receptacle 210 connected to the destination device, the active signal management processes could be applied by the source device to generate a processed digital signal and the active signal management receive circuitry 110 at the cable receptacle 110 could receive the processed signal and perform one or more corresponding active signal management processes to recover the original digital signal and provide the recovered signal to the destination device via the destination device interface 204.

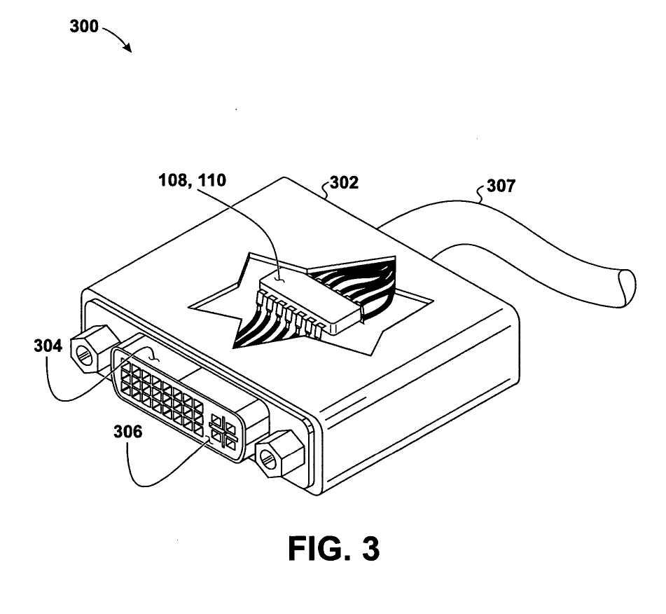

Referring to FIG. 3, a plan view of a cable receptacle 300 of a cable assembly is illustrated in accordance with at least one embodiment of the present disclosure. The cable receptacle 300 can represent, for example, either or both of the cable receptacle 208 or the cable receptacle 210 of the cable 206. The depicted example of FIG. 3 illustrates a cable receptacle compatible with a DVI cable interface. However, it will be appreciated that the cable adaptor 500 can be configured to be compatible with any of a variety of cable interfaces, such as an HDMI cable interface, a DisplayPort interface, a UDI cable interface, a USB cable interface, an IEEE 1394 cable interface, and the like.

The cable receptacle 300 includes a housing 302 fixed to the cable body 207, whereby the active signal management transmit circuitry 108 or the active signal management receive circuitry 110 is disposed within the housing 302. For purposes of illustration, the active signal management transmit circuitry 108/active signal management receive circuitry 110 is illustrated as a single IC, such as an ASIC or FPGA, within the housing 302. However, it will be appreciated that the active signal management circuitry can be implemented as multiple discrete circuit devices. The cable receptacle 300 further includes a receptacle interface 304 that is removably attachable to a DVI cable interface of the source device or a DVI interface of the destination device. The receptacle interface 304 can be attached to the DVI interface of a corresponding device via mechanical friction between the receptacle interface 304 and the corresponding receptacle of the DVI interface, via clamps, screws or other mechanical fastening means, and the like.

Disposed at the external face of the receptacle interface 304 is a pin interface 306 configured to provide electrical connections between the device-side pins (male or female) of the active signal management circuitry and the corresponding pins of the DVI interface of the device to which the cable receptacle 302 is removably attached. In the example of FIG. 3, the pin interface 306 represents a DVI-D female dual link pin interface. The cable-side pins of the active signal management circuitry are connected to corresponding conductive interconnects (e.g., wiring) extending from the cable receptacle 300 along the cable body 207 to the other cable receptacle. As noted above, these conductive interconnects can be configured in twisted pair arrangements so as to reduce potential EMI emissions and signal distortion.

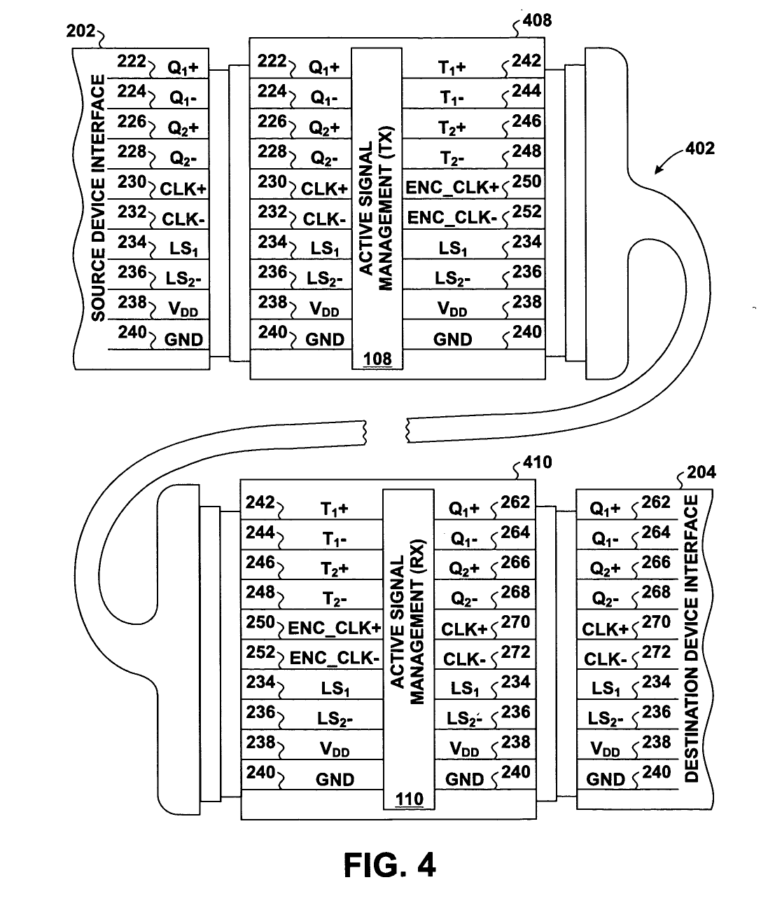

Referring to FIG. 4, an implementation of an active signal management system in cable adaptors is illustrated in accordance with at least one embodiment of the present disclosure. In many instances, it may be difficult to implement the active signal management system of FIG. 1 in at the source device and destination device or entirely in a cable as illustrated by FIGS. 2 and 3. For example, a user may have previously purchased a conventional DVD player and a conventional HDTV and paid an installer a considerable sum of money to have a passive cable installed behind the walls and ceiling of a home theatre to connect the DVD player and the HDTV. Thus, the replacement of the conventional DVD player and the HDTV with new devices that implement the active signal management techniques described herein may be cost prohibitive, as may be the removal and replacement of the passive cable with an active cable interconnect utilizing active signal management circuitry as described herein. Accordingly, in one embodiment, one or more cable adaptors may be used at either end of a passive cable to provide active signal management for signals transmitted via the passive cable.

In the depicted example, the source device interface 202 is connected to the destination device interface 204 via a conventional passive cable 402 (e.g., a standard DVI cable) and one or both of a transmit-side cable adaptor 408 and a receive-side cable adaptor 410. The transmit-side cable adaptor 408 incorporates the active signal management transmit circuitry 108 to apply one or more active signal management processes to high-speed data/clock signals provided by the source device interface 202, wherein the resulting processed data/clock signals are provided for transmission via the conductive wiring of the conventional passive cable 402. The receive-side cable adaptor 410 incorporates the active signal management receive circuitry 110 to apply one or more active signal management processes to the transmitted processed data/clock signals to recover the original high-speed data/clock signals output by the source device interface 202 and provides the recovered high-speed data/clock signals to the destination device interface 204 for processing by the destination device.

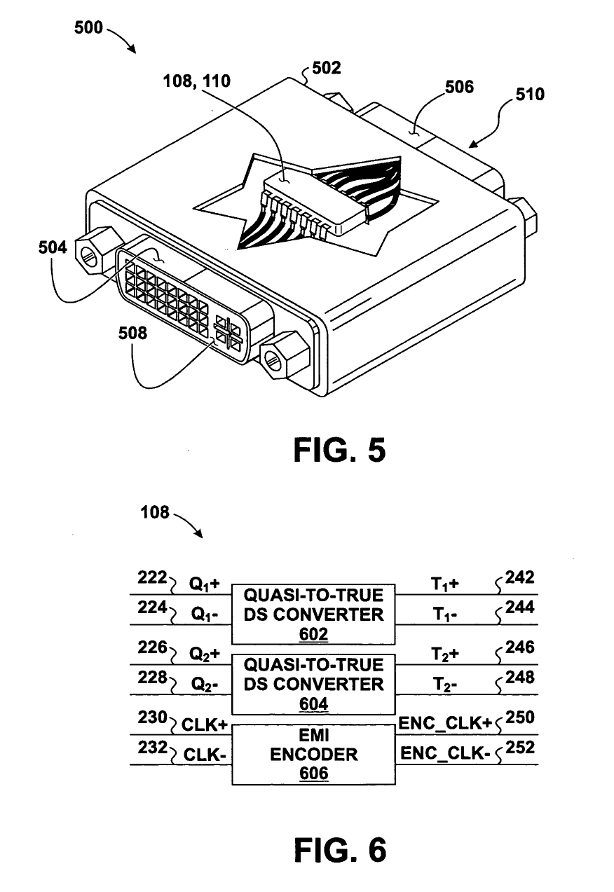

Referring to FIG. 5, a plan view of a cable adaptor 500 incorporating active signal management circuitry is illustrated in accordance with at least one embodiment of the present disclosure. The cable adaptor 500 can represent either of the cable adaptors 408 or 410 of FIG. 4. The depicted example of FIG. 5 illustrates a cable adaptor 500 compatible with a DVI cable interface. However, it will be appreciated that the cable adaptor 500 can be configured to be compatible with any of a variety of cable interfaces, such as an HDMI cable interface, a DisplayPort interface, a UDI cable interface, a USB cable interface, an IEEE 1394 cable interface, and the like.

The cable adaptor 500 includes a housing 502 in which one or both of the active signal management transmit circuitry 108 or the active signal management receive circuitry 110 are disposed. The cable adaptor 500 further includes receptacle interfaces 504 and 508 that are removably attachable to the DVI interface of the source device or the destination device and the receptacle interface of the corresponding cable receptacle of the conventional passive cable 402 (FIG. 4). Disposed at the external face of the receptacle interface 504 is a pin interface 508 configured to provide electrical connections between the device interface and the device-side pins (male or female) of the active signal management circuitry of the cable adaptor 500. Likewise, disposed at the external face of the receptacle interface 506 is a pin interface 510 configured to provide electrical connections between the receptacle interface of the corresponding cable receptacle and the cable-side pins (male or female) of the active signal management circuitry of the cable adaptor 500. To illustrate, assuming that the source device interface 202 and the destination device interface 204 are DVI-D dual link female interfaces and, consequently, the receptacle interfaces of both ends of the conventional passive cable 402 are DVI-D dual link male interfaces, the receptacle interface 504 and pin interface 508 would be a DVI-D dual link male interface to connect to the DVI-D dual link female interface of the source/destination device, while the receptacle interface 506 and the pin interface 510 would be a DVI-D dual link female interface to connect to the DVI-D dual link male interface of the corresponding cable receptacle of the conventional passive cable 402. The receptacle interfaces 504 and 506 can be attached to the DVI interface of a corresponding device via mechanical friction, via clamps, screws or other mechanical fastening means, and the like.

As illustrated by FIGS. 2-DD, the active signal management circuitry can be employed at the source/destination devices, at the cable, at one or more cable adaptors connected between a cable and the source/destination device, or any combination thereof. Thus, active signal management processes can be employed while facilitating compatibility between devices. To illustrate, in some instances, neither the source device nor the destination device has active signal management. Accordingly, a conventional passive cable can be used along with one or more active cable adaptors that employ active signal management circuitry so as to improve the signal transmission fidelity and reduce EMI between the source device and the destination device. Alternately, a cable employing active signal management circuitry at one or both ends can be employed between a conventional source device and a conventional destination device so as to improve signal transmission fidelity and reduce EMI. In other instances, one of the source device or the destination device may employ active signal management whereas the other does not. Accordingly, a cable or cable adaptor implementing active signal management on the end opposite of the enabled device can be used to provide active signal management across the cable interface. To illustrate, a manufacturer may manufacture HDTVs that employ active signal management receive circuitry at their DVI interfaces. Accordingly, the manufacturer or third party may supply a cable interconnect that has active signal management transmit circuitry at the cable end opposite of the end that connects to the HDTV's DVI interface so as to provide active signal management across the cable interconnect. Alternately, the manufacturer or third party may supply a source device-side cable adaptor that connects between the source device (e.g., a DVD player) and the cable, whereby the source device-side cable adaptor implements active signal management transmit circuitry so as to provide active signal management across the cable interconnect. Accordingly, it will be appreciated that the implementation of the active signal management circuitry at one or both ends of a cable, at one or more cable adaptors between the source device and the destination device, or a combination thereof, enables improved signal transmission characteristics while allowing for backward compatibility with devices that do not employ active signal management.

FIGS. 6-24 illustrate various active signal management processes of the active signal management transmit circuitry 108 (FIG. 1) and various active signal management processes of the active signal management receive circuitry 110 (FIG. 1). Although particular combinations of processes are described for illustrative purposes, the active signal management transmit circuitry 108 and the active signal management receive circuitry 110 can implement any combinations of the processes described herein without departing from the scope of the present disclosure.

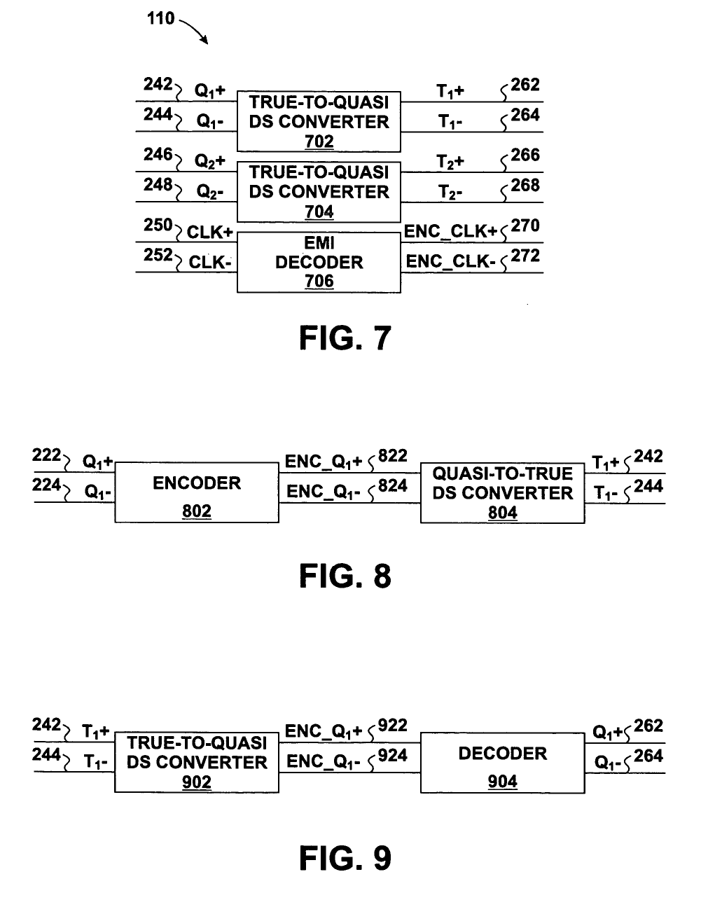

Referring to FIGS. 6 and 7, an implementation of the active signal management transmit circuitry 108 (FIG. 6) and the corresponding implementation of the active signal management receive circuitry 110 (FIG. 7) are illustrated in accordance with at least one embodiment of the present disclosure.

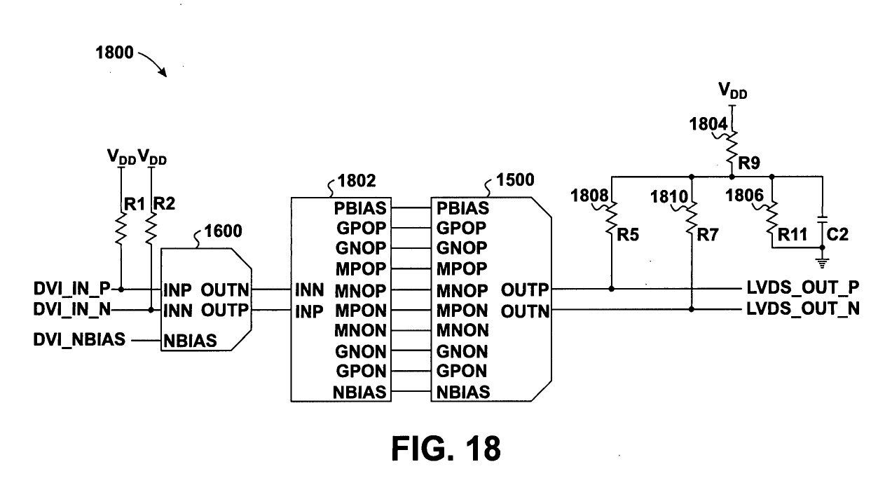

In the depicted implementation of FIG. 6, the active signal management transmit circuitry 108 includes quasi-to-true differential signaling converters 602 and 604 and an EMI encoder 606. The quasi-to-true differential signaling converter 602 converts the first quasi differential data signal (signal Q₁⁺ (222) and its complement signal Q₁⁻ (224)) from a quasi differential signal into a true differential signal, thereby generating the first true differential data signal (signal T₁⁺ (242) and its complement signal T₁⁻ (244)) and provides the first true differential data signal for transmission via paired conductive interconnects. Similarly, the quasi-to-true differential signaling converter 604 converts the second quasi differential data signal (signal Q₂⁺ (226) and its complement signal Q₂⁻ (228)) from a quasi differential signal into a true differential signal, thereby generating the second true differential data signal (signal T₂⁺ (246) and its complement signal T₂⁻ (248)) and provides the second true differential data signal for transmission via paired conductive interconnects. An implementation of a quasi-to-true differential signaling converter is illustrated herein with reference to FIG. 18.

The EMI encoder 606 encodes the quasi differential clock signal (signal CLK⁺ (230) and its complement signal CLK⁻ (232)) using a random or pseudo-random digital noise signal to generate an encoded differential clock signal (signal ENC_CLK⁺ (250) and its complement signal ENC_CLK⁻ (252)) and provides the encoded differential clock signal for transmission via paired conductive interconnects. Further, in one embodiment, the quasi differential clock signal can be converted to a true differential clock signal for transmission. Implementations of an EMI encoder/decoder is illustrated herein with reference to FIGS. 28-38.

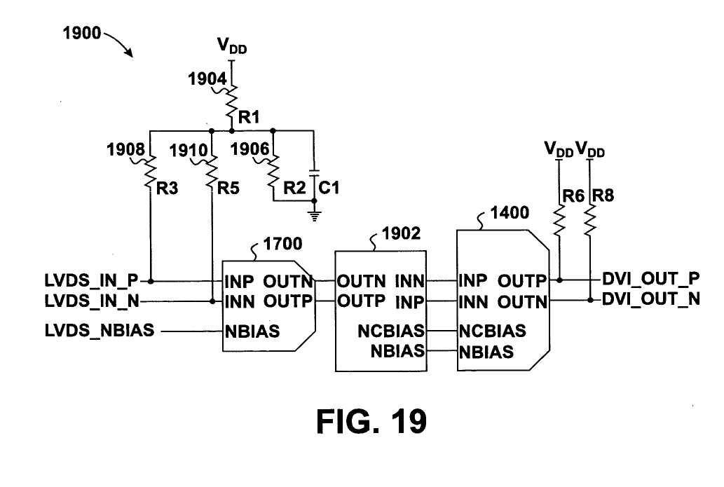

In the depicted example of FIG. 7, the active signal management receive circuitry 110 includes true-to-quasi differential signaling converters 702 and 704 and an EMI decoder 706. The true-to-quasi differential signaling converter 702 converts the first true differential data signal (signal T₁⁺ (242) and its complement signal T₁⁻ (244)) from a true differential signal into a quasi differential signal, thereby generating the recovered first quasi differential data signal (signal Q₁⁺ (262) and its complement signal Q₁⁻ (264)) and provides the recovered first quasi differential data signal to a destination device for processing. Similarly, the true-to-quasi differential signaling converter 704 converts the second true differential data signal (signal T₂⁺ (246) and its complement signal T₁⁻ (248)) from a true differential signal into a quasi differential signal, thereby generating the recovered second quasi differential data signal (signal Q₂⁺ (266) and its complement signal Q₂⁻ (266)) and provides the recovered second quasi differential data signal to the destination device for processing. An implementation of a true-to-quasi differential signaling converter is illustrated herein with reference to FIG. 19.

The EMI decoder 706 decodes the encoded differential clock signal (signal ENC_CLK⁺ (250) and its complement signal ENC_CLK⁻ (252)) using one or more random or pseudo-random digital noise signals synched to the corresponding digital noise signal(s) of the EMI encoder 606 to generate a recovered differential clock signal (signal CLK⁺ (270) and its complement signal CLK⁻ (272)) and provides the recovered differential clock signal to the destination device. Further, in one embodiment, the recovered differential clock signal, if transmitted as a true differential clock signal, can be converted to a quasi differential clock signal for use by the destination device. Implementations of an EMI encoder/decoder are illustrated herein with reference to FIGS. 28-40.

Referring to FIGS. 8 and 9, another implementation of the active signal management transmit circuitry 108 (FIG. 8) and the corresponding implementation of the active signal management receive circuitry 110 (FIG. 9) are illustrated in accordance with at least one embodiment of the present disclosure.

In addition to converting a high-speed data signal from a quasi differential signal to a true differential signal for transmission, it may also be advantageous to encode the high-speed data signal. Accordingly, as illustrated by FIG. 8, the active signal management transmit circuitry 108 can include an EMI encoder 802 and a quasi-to-true differential signaling converter 804 for one or more of the high-speed data/clock signals to be transmitted. To illustrate, the EMI encoder 802 encodes the first quasi differential data signal (signal Q₁⁺ (222) and its complement signal Q₁⁻ (224)) to generate an encoded quasi differential data signal (signal ENC_Q₁⁺ (GG22) and its complement signal ENC_Q₁⁻ (GG24)). The quasi-to-true differential signaling converter 804 then converts the encoded quasi differential data signal from a quasi differential signal into a true differential signal, thereby generating the first true differential data signal (signal Tₗ⁺ (242) and its complement signal T₁⁻ (244)) and provides the first true differential data signal for transmission via the cable body 207 (FIG. 2). Thus, in the example of FIG. 8, the first true differential data signal is an encoded representation of the first quasi differential data signal. In an alternate embodiment, the first quasi differential data signal is first converted to a true differential data signal and the true differential data signal is then encoded and provided for transmission.

In the depicted example of FIG. 9, the active signal management receive circuitry 110 includes a true-to-quasi differential signaling converter 902 and an EMI decoder 904 for one or more received high-speed data/clock signals. To illustrate, the true-to-quasi differential signaling converter 702 converts the first true differential data signal (signal T₁⁺ (242) and its complement signal T₁⁻ (244)) from a true differential signal into a quasi differential signal, thereby generating a recovered encoded quasi differential data signal (signal ENC_Q₁⁺ (HH22) and its complement signal ENC_Q₁⁻ (HH24)). The EMI decoder 704 then decodes the recovered encoded quasi differential data signal to generate the recovered first quasi differential data signal (signal Q₁⁺ (262) and its complement signal Q₁⁻ (2644)) in an unencoded form. The recovered first quasi differential data signal is provided to the destination device for processing.

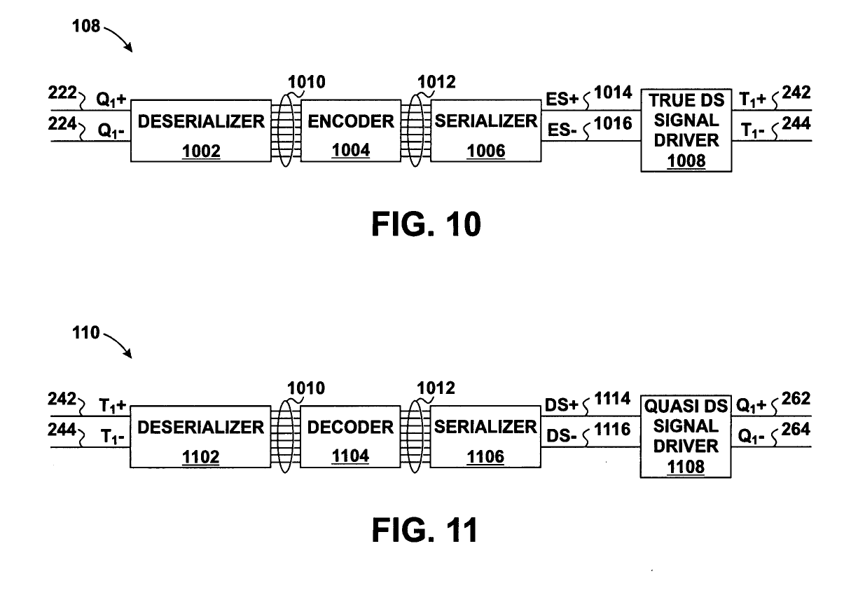

Referring to FIGS. 10 and 11, another implementation of the active signal management transmit circuitry 108 (FIG. 8) and the corresponding implementation of the active signal management receive circuitry 110 (FIG. 9) are illustrated in accordance with at least one embodiment of the present disclosure. In certain instances, it may be advantageous to deserialize a high-speed data signal into a plurality of parallel signals and then reserialize the plurality of parallel signals to generate a reserialized data signal. This active signal management process of deserializing and then reserializing a serialized digital signal often provides the benefit of signal retiming. It will be appreciated that retiming is a technique used to reduce the impact of the interconnect (impedance mismatches, inter-symbol interference, dispersion, intra-pair skew, differential to common mode conversion and visa-versa and the like) from the subsequent eye diagram. These effects can cause significant jitter in the serial data stream, increasing the bit error ratio (BER), and decrease the likelihood of error free data recovery. By retiming the data, jitter contributed by the interconnect is removed as it is being resampled and retimed from the extracted or regenerated clock source.

Accordingly, as illustrated by FIG. 10, the active signal management transmit circuitry 108 can include a deserializer 1002 and a serializer 1006 and a true differential signaling transmitter 1008. The deserializer 1002 converts the serial-format first quasi differential data signal (signal Q₁⁺ (222) and its complement signal Q₁⁻ (224)) to a set 1010 of parallel digital signals. The serializer 1006 then serializes a set 1012 of parallel digital signals based on the set 1010 of parallel digital signals into a serialized signal (e.g., a differential signal represented by signal S⁺ (signal 1014) and its complement S⁻(signal 1016) or, alternately, a single ended digital signal). The true differential signaling transmitter 1008 then transmits the serialized digital signal as a first true differential data signal (signal T₁⁺ (242) and its complement signal T₁⁻ (244)). An implementation of a true differential signaling transmitter is illustrated with reference to FIG. 15.

In one embodiment, the set 1012 of parallel digital signals is the set 1010 of parallel digital signals. In another embodiment, the set 1012 of parallel digital signals comprises the parallel digital signals resulting from the application of one or more active signal management processes to some or all of the digital signals of the set 1010. For example, in the illustrated embodiment, the active signal management transmit circuitry 208 further includes an encoder 1004 that encodes each parallel data signal of the set 1010 to generate the set 1012 of parallel digital signals. In one embodiment, the encoder 1004 includes an EMI encoder to EMI encode the parallel digital signals of the set 1010 to generate the set 1012. In one embodiment, each of the parallel digital signals is encoded using the same noise source. In another embodiment, different noise sources are used to encode different parallel digital signals. As another example, encoder 1004 can include a symbol encoder that encodes one or more occurrences of a data symbol that occurs periodically or substantially periodically in the digital signal. In yet another embodiment, the encoder 1004 can include an encryption module to encrypt the information represented by the set 1010 of parallel digital signals to generate the set 1012 of parallel digital signals that are encrypted representations of the parallel digital signals of the set 1010. Any of a variety of other active signal management processes, or combinations thereof, may be applied to some or all of the set 1010 of parallel digital signals without departing from the scope of the present disclosure.

In the depicted example of FIG. 11 corresponding to the example of FIG. 10, the active signal management receive circuitry 210 includes a deserializer 1102, a serializer J06, and a quasi differential signaling transmitter 1108. The deserializer 1102 converts the serialized first true differential data signal (signal T₁⁺ (242) and its complement signal T₁⁻ (244)) to a set 1110 of parallel digital signals. The serializer 1106 then serializes a set 1112 of parallel digital signals based on the set 1110 into a serialized signal (e.g., a differential data signal represented by signal DS⁺ (signal 1114) and its complement signal DS⁻ (signal 1116) or a single ended digital signal). The quasi differential signaling transmitter 1108 then transmits the serialized data signal as the recovered first quasi differential data signal (signal Q₁⁺ (262) and its complement signal Q₁⁻ (264)) for provision to the destination device. An implementation of a quasi differential signaling transmitter is illustrated with reference to FIG. 18.

In one embodiment, the set 1112 of parallel digital signals is the set 1110 of parallel digital signals. In another embodiment, the set 1112 of parallel digital signals comprises the parallel digital signals resulting from the application of one or more active signal management processes to some or all of the digital signals of the set 1110. For example, in the illustrated embodiment, the active signal management transmit circuitry 208 further includes a decoder 1104 that encodes each parallel data signal of the set 1110 to generate the set 1112 of parallel digital signals. In one embodiment, the decoder 1104 includes an EMI decoder, where each of the parallel digital signals is decoded using the same noise source or different noise sources. In another embodiment the decoder 1104 includes a symbol decoder that decodes one or more occurrences of an encoded data symbol that occurs periodically or substantially periodically in the received digital signal. In yet another embodiment, the decoder 1104 can include a decryption module to decrypt the set 1110 of parallel digital signals. Any of a variety of other active signal management processes, or combinations thereof, may be applied to some or all of the set 1110 of parallel digital signals without departing from the scope of the present disclosure.

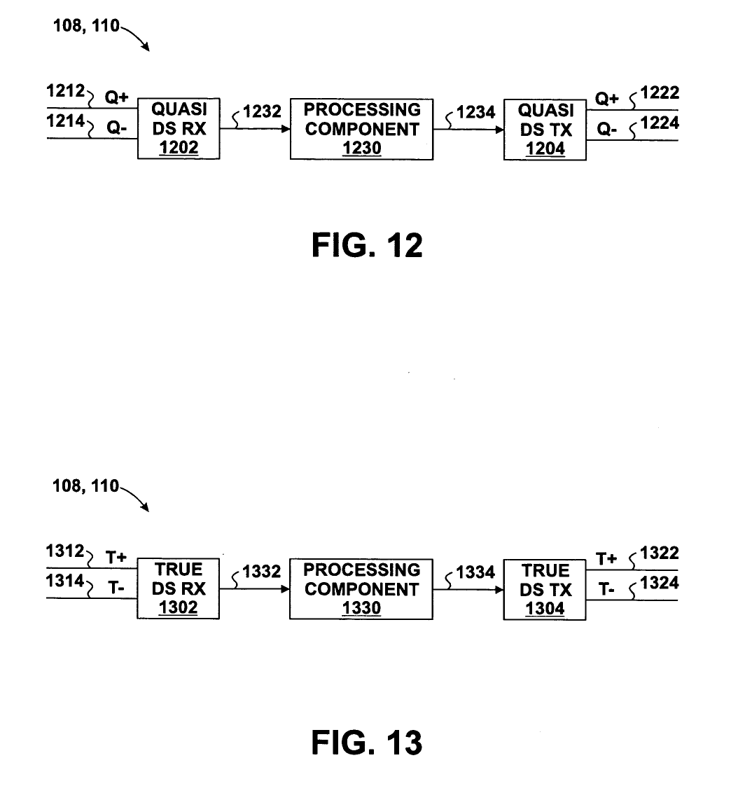

Referring to FIGS. 12 and 13, other implementations of the active signal management transmit circuitry 108 (FIG. 8) or the active signal management receive circuitry 110 (FIG. 9) are illustrated in accordance with at least one embodiment of the present disclosure. Although various implementations of a cable assembly are described herein as receiving a quasi differential signal at one end and providing a quasi differential signal at the other end, while internally transmitting the signal as a true differential signal, in other implementations it may be advantageous to maintain the signal in its original signaling format (e.g., maintain the signal as a quasi differential signal throughout the cable assembly or as a true differential signal throughout the cable assembly). Accordingly, FIG. 12 illustrates an implementation of the active signal management transmit circuitry 108 and/or the active signal management receive circuitry 110 as receiving a quasi differential signal and providing a quasi differential signal. FIG. 13 illustrates an implementation of the active signal management transmit circuitry 108 and/or the active signal management receive circuitry 110 as receiving a true differential signal and providing a true differential signal.

In the depicted example of FIG. 12, the active signal management circuitry includes a quasi differential signal receiver 1202 and a quasi differential signal transmitter 1204. The quasi differential signal receiver 1202 receives a quasi differential signal represented by signal component Q⁺ (signal 1212) and signal component Q⁻ (signal 1214) and provides the information represented by the received quasi differential signal to the quasi differential signal transmitter 1204 (as either a single ended signal or a differential signal) for transmission as an output quasi differential signal represented by signal component Q+ (signal 1222) and signal component Q⁻ (signal 1224). The input to the quasi differential signal receiver 1202 can come from a cable interconnect and the output of the quasi differential signal transmitter 1204 can be provided to a destination device (i.e., the circuitry of FIG. 12 is disposed at the receive end of a cable interconnect). Alternately, the input to the quasi differential signal receiver 1202 can come from a source device and the output of the quasi differential signal transmitter 1204 can be provided paired conductive interconnects of a cable assembly for transmission to the other end of the cable assembly (i.e., the circuitry of FIG. 12 is disposed at the transmit end of a cable interconnect).

In one embodiment, the received signal is provided directly from the quasi differential receiver 1202 to the quasi differential transmitter 1204. In another embodiment, the active signal management circuitry includes one or more processing components 1230 to process the signal 1232 output by the quasi differential signal receiver 1202 and provide the resulting processed signal 1234 to the quasi differential signal transmitter 1204 for transmission. The processing components 1230 can include other active signal management circuitry, such as a skew management module, a signal amplifier, an encoder (symbol, EMI, encryption), and the like.

In the depicted example of FIG. 13, the active signal management circuitry includes a true differential signal receiver 1302 and a true differential signal transmitter 1304. The true differential signal receiver 1302 receives a true differential signal represented by signal component Q⁺ (signal 1312) and signal component Q⁻ (signal 1314) and provides the information represented by the received true differential signal to the true differential signal transmitter 1304 (as either a single ended signal or a differential signal) for transmission as an output true differential signal represented by signal component Q+ (signal 1322) and signal component Q⁻ (signal 1324). The input to the true differential signal receiver 1302 can come from a cable interconnect and the output of the true differential signal transmitter 1304 can be provided to a destination device (i.e., the circuitry of FIG. 13 is disposed at the receive end of a cable interconnect). Alternately, the input to the true differential signal receiver 1302 can come from a source device and the output of the true differential signal transmitter 1304 can be provided paired conductive interconnects of a cable assembly for transmission to the other end of the cable assembly (i.e., the circuitry of FIG. 13 is disposed at the transmit end of a cable interconnect).

In one embodiment, the received signal is provided directly from the true differential receiver 1302 to the true differential transmitter 1304. In another embodiment, the active signal management circuitry includes one or more processing components 1330 to process the signal 1332 output by the true differential signal receiver 1302 and provide the resulting processed signal 1334 to the true differential signal transmitter 1304 for transmission. The processing components 1330 can include other active signal management circuitry, such as a skew management module, a signal amplifier, an encoder (symbol, EMI, encryption), and the like.

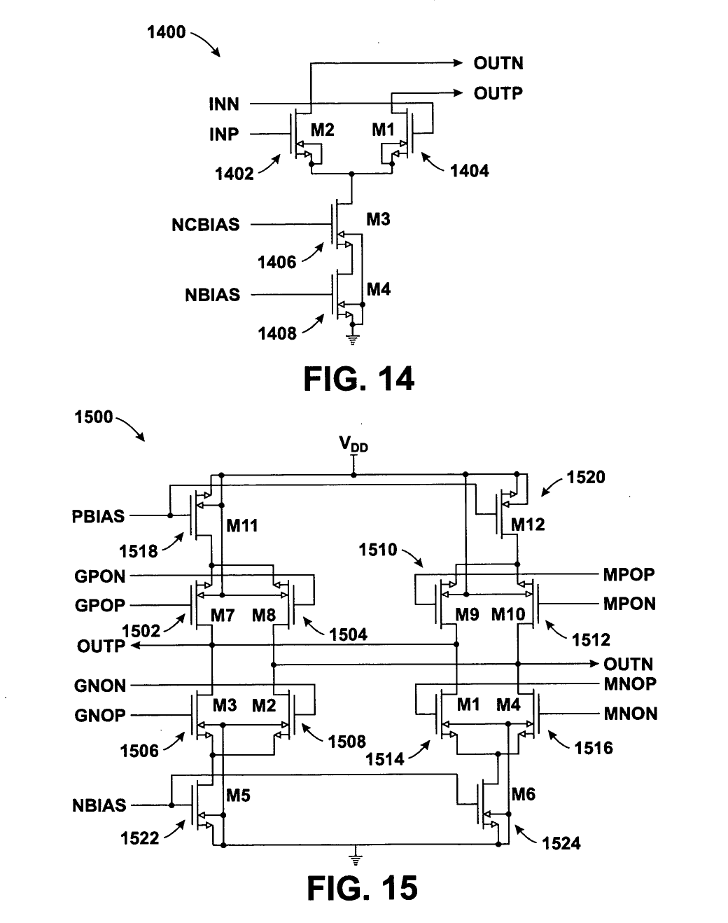

Referring to FIG. 14, an implementation of a quasi differential signal transmitter 1400 is illustrated in accordance with at least one embodiment of the present disclosure. The depicted example illustrates a current mode logic (CML)-based signal transmitter.

The quasi differential signal transmitter 1400 includes driving transistors 1402 and 1404 to receive the two components of a differential signal (i.e., signals INP and INN, respectively) and to provide a quasi differential output signal represented by the components OUTP and OUTN, respectively. In the illustrated implementation, the quasi differential signal transmitter 1400 is a current sink and relies on an external resistive pull-up. A single ended input version can be achieved by driving the INP signal with the single ended signal, which is also routed to an inverter. The output of the inverter would drive the INN signal.

The quasi differential signal transmitter 140 further includes bias transistors 1406 and 1408 to receive biasing signals NCBIAS and NBIAS, respectively, which set the operating current (i.e., drive strength) of the quasi differential transmitter 1400. In one embodiment, the NCBIAS biasing signal is synchronously modulated to allow for pre-emphasis or de-emphasis of the output signal.

Referring to FIG. 15, an implementation of a true differential signal transmitter 1500 is illustrated in accordance with at least one embodiment of the present disclosure. The depicted example illustrates a low voltage differential signaling (LVDS)-based signal transmitter.

The true differential signal transmitter 1500 includes driving transistors 1502, 1504, 1506, 1508, 1510, 1512, 1514 and 1512 to receive input signals GPOP, GPON, MPOP, MPON, GNOP, GNON, MNOP and MNON, respectively. GPON/GPOP and MNON/MNOP are driven during one phase of the signal and GNOP/GNON and MPOP/MPON are driven during the complementary phase, thus acting as a low noise, no current modulating through the VDD rail. The signals OUTP and OUTN represent the components of the resulting true differential signal.

The true differential signal transmitter 1500 further includes bias transistors 1518 and 1510 to receive a bias signal PBIAS and bias transistors 1522 and 1524 to receive a biasing signal NBIAS. Operating current (which can include preemphasis) is set by the voltage on the biasing signals PBIAS and NBIAS. It will be appreciated that the currents set by bias transistors 1522/1524 and 1518/1520 typically are precisely matched. Further, the biasing signals PBIAS and NBIAS can be modulated to allow for preemphasis or deemphasis of the output signal. To illustrate, preemphasis/deemphasis logic can implement preemphasis/deemphasis prior to the differential input transmitters. A one or more D-flops can be utilized to store the state of the last logic level and subsequent logic levels driven to the true differential signal transmitter 1500 and an XOR gate can be used to modulate the NBIAS/PBIAS current reference, thereby selectively adding current drive during high frequency bit transitions.

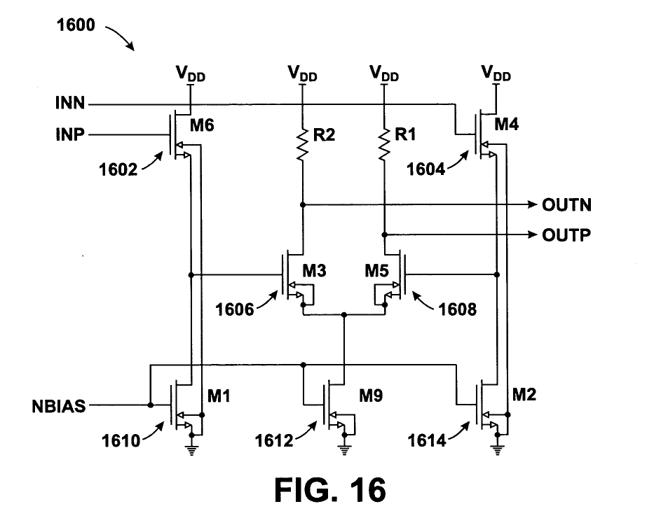

Referring to FIG. 16, an implementation of a quasi differential signal receiver 1600 is illustrated in accordance with at least one embodiment of the present disclosure. The depicted example represents a CML-based receiver.

The quasi differential signal receiver 1600 includes receiving transistors 1602 and 1604 to receive the components INP and INN of a received quasi differential signal and driving transistors 1606 and 1608 to provide the quasi differential signal as components OUTP and OUTN, respectively. The quasi differential signal receiver 1600 further includes biasing transistors 1600, 1612 and 1614 to receive a biasing signal NBIAS, where the biasing signal NBIAS can be modulated to provide for equalization.

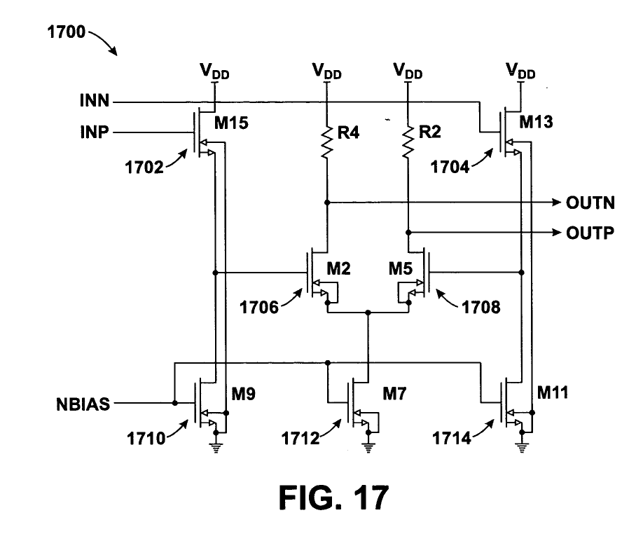

Referring to FIG. 17, an implementation of a true differential signal receiver 1700 is illustrated in accordance with at least one embodiment of the present disclosure. The depicted example represents an LVDS-based receiver.

The true differential signal receiver 1700 includes receiving transistors 1702 and 1704 to receive the components INP and INN of a received true differential signal and driving transistors 1706 and 1708 to provide the true differential signal as components OUTP and OUTN, respectively. The true differential signal receiver 1700 further includes biasing transistors 1710, 1712 and 1714 to receive a biasing signal NBIAS, where the biasing signal NBIAS can be modulated to provide for equalization.

Referring to FIG. 18, an implementation of a quasi-to-true differential signaling converter 1800 is illustrated in accordance with at least one embodiment of the present disclosure. In the depicted example, the quasi-to-true differential signaling converter 1800 is implemented to convert, for example, a DVI-compliant CML-based signal to an LVDS-based signal.

The quasi-to-true differential signaling converter 1800 includes the quasi differential signal receiver 1600 (FIG. 16), transmission logic 1802, and the true differential signal transmitter 1500. The quasi-to-true differential signaling converter 1800 further includes resistors 1804 (e.g., 130 Ohms) and 1806 (e.g., 82.5 Ohms) that act to supply a common mode voltage and resistors 1808 and 1810 that act to provide both differential termination and common mode termination.

The quasi differential signal receiver 1600 receives an quasi differential signal, such as a CML-based differential signal representing a DVI transmission having components DVI_IN_P and DVI_IN_N and provides an output signal having component OUTP and OUTN based on a biasing signal DVI_NBIAS. The transmission logic 1802 receives the differential signal output by the quasi differential signal receiver 1600 and processes the signal for output to the true differential signal transmitter 1500. The processing can include, for example, logic translation, pre-emphasis implementation, de-emphasis implementation, and the like. The transmission logic 1802 further is adapted to provide the signals GPOP/GPON, GNOP/GNON, MPOP/MPON and MNOP/MNON during their respective phases based on the input signal. The true differential signal transmitter 1500 receives the signals GPOP/GPON, GNOP/GNON, MPOP/MPON and MNOP/MNON and provides an output true differential signal represented by the components LVDS_OUT_P and LVDS_OUT_N.

Referring to FIG. 19, an implementation of a true-to-quasi differential signaling converter 1900 is illustrated in accordance with at least one embodiment of the present disclosure. In the illustrated example, the true-to-quasi differential signaling converter 1900 represents an LVDS-to-CML converter for use in converting, for example, an LVDS signal to a DVI-compliant CML-based signal.

The true-to-quasi differential signaling converter 1900 includes the true differential signal receiver 1700 (FIG. 17), receiver logic 1902, and the quasi differential signal transmitter 1400. The true-to-quasi differential signaling converter 1900 further includes resistors 1904 and 1906 that act to supply a common mode voltage reference and resistors 1908 and 1910 that act to provide both differential termination and common mode termination.

The true differential signal receiver 1700 receives a true differential signal, such as an LVDS-based differential signal representing a DVI transmission (output by, for example, the quasi-to-true differential signaling converter 1800 of FIG. 18) having components LVDS_IN_P and LVDS_IN_N and provides an output signal having components OUTP and OUTN based on a biasing signal LVDS_NBIAS. The receiver logic 1902 receives the differential signal output by the true differential signal receiver 1700 and processes the signal for output to the quasi differential signal transmitter 1400. The processing can include, for example, logic translation, pre-emphasis implementation, de-emphasis implementation, and the like. The quasi differential signal transmitter 1400 receives the signals output by the receiver logic 1902 and provides an output quasi differential signal represented by the components DVI_OUT_P and DVI_OUT_N.

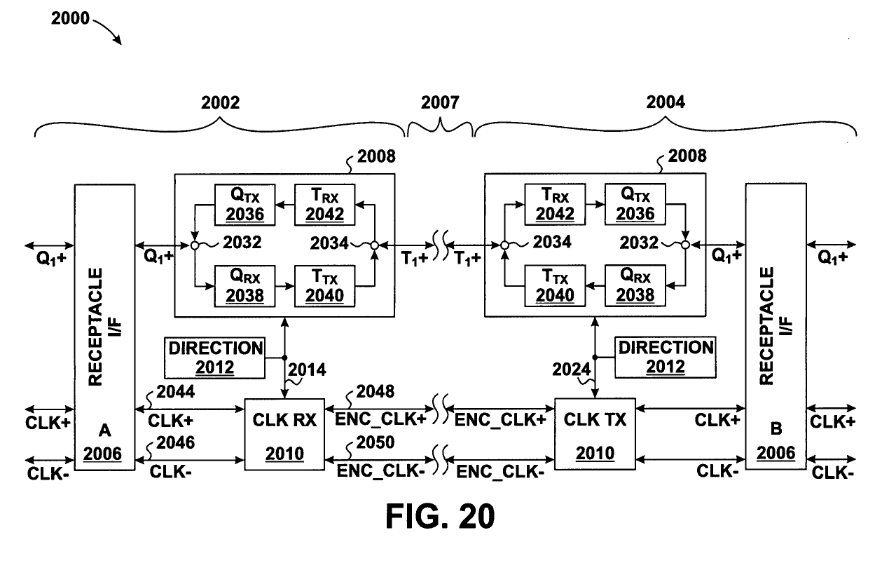

As illustrated by FIGS. 3 and 5, it can be advantageous to incorporate the active signal management circuitry into a cable or into a cable adaptor at one or both ends of a cable interconnect. FIGS. 3 and 5 illustrate a particular implementation whereby the active signal management transmit circuitry 108 (FIG. 1) is incorporated at one end of the cable or in a cable adaptor connected to the one end of the cable, while the active signal management receive circuitry 110 is incorporated at the other end of the cable or in a cable adaptor connected to the other end of the cable. In such instances, it will be appreciated that the cable or cable adaptor is unidirectional, i.e., each cable receptacle is specific to only to the transmit side of the receive side. An installer or user therefore would need to ensure that the cable or the cable adaptor is connected in the proper orientation. In order to reduce the reliance on ensuring the proper connection orientation, in at least one embodiment, the active signal management circuitry can be implemented in a cable assembly such that both the active signal management transmit circuitry 108 and the active signal management receive circuitry 110 are implemented together at the end of the cable assembly so as to allow either cable end to be connected to either a source device or a destination device, thereby facilitating ease of installation. Example implementations of the bidirectional approach are illustrated with reference to FIGS. 20-27.

Referring to FIG. 20, a bidirectional active signal management system 2000 is illustrated in accordance with at least one embodiment of the present disclosure. As illustrated, the bidirectional system 2000 includes two sides, side 2002 and 2004 (also referred to herein as sides A and B, respectively). For ease of discussion, the implementation of FIG. 20 is described in the context of a cable, such as the cable 206 (FIG. 2). Accordingly, the side 2002 represents the circuitry implemented at one cable receptacle and the side 2002 represents the circuitry implemented at the other cable receptacle, whereby the sides 2002 and 2004 (i.e., the cable receptacles) are connected via a cable body 2007. For purposes of clarity, FIG. 20 illustrates the logic for only a single signal component, signal Q₁⁺, of a high-speed data quasi differential signal and a corresponding clock signal represented by high-speed quasi differential signal components CLK⁺ and CLK⁻. The same or similar technique may be used for other digital signals as appropriate.

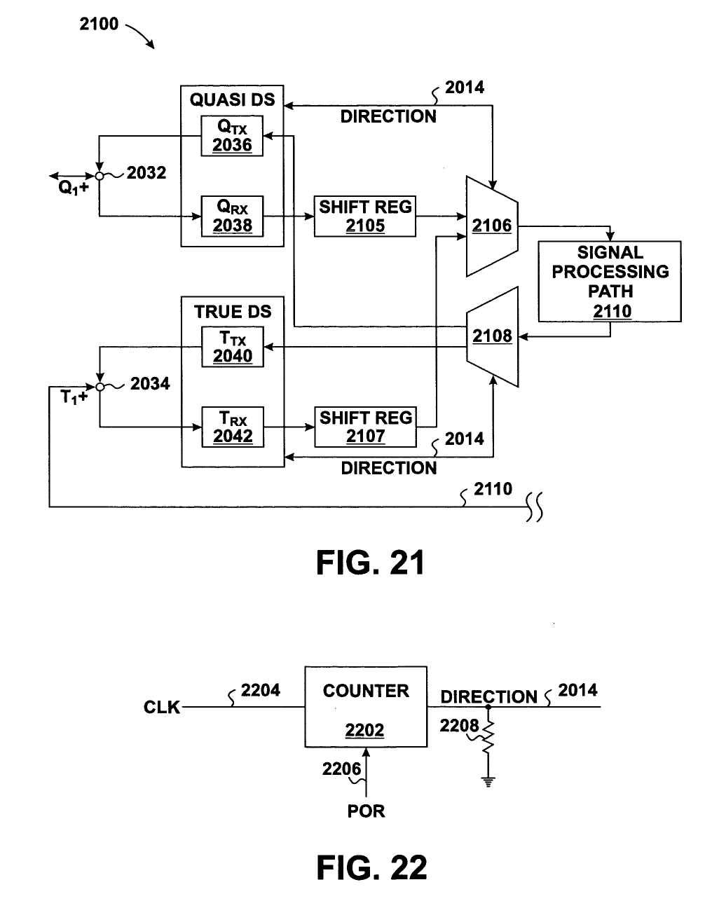

The sides 2002 each include a connector to a device, such as a receptacle interface 2006, a bidirectional circuit component 2008, a clock transceiver 2010, and direction detection module 2012. The cable receptacle interface 2006 interfaces with the one or more signal pins of the corresponding device, including a pin associated with the signal component Q₁⁺ and pins associated with the clock components CLK⁺ and CLK⁻. The direction module 2012 detects the direction of data flow for transmitted signals, i.e., whether the signals are transmitted from side 2002 to side 2004 or from side 2004 to side 2002, and provides a direction signal (direction signal 2014 (direction A) for side 2002 and direction signal 2024 (direction B) for side 2004). As discussed in greater detail with reference to FIG. 21, in one embodiment, the direction module 2012 determines the direction of data flow by detecting a clock signal at the side at which it is located.

The bidirectional circuit component 2008 includes bidirectional signal interfaces 2032 and 2034, a quasi differential transmitter 2036, a quasi differential receiver (Q_{RX}) 2038, a true differential transmitter (T_{TX}) 2040, a true differential receiver (T_{Rx}) 2042, and active signal management circuitry (not shown). The bidirectional signal interface 2032 is connected to the pin interface of the receptacle interface 2006 associated with the signal Q₁⁺ and the bidirectional signal interface 2034 is connected to the conductive interconnect (e.g., a conductive wire) of the cable body 2007 used to transmit the corresponding converted signal T₁⁺ to the other side of the cable interconnect. The quasi differential transmitter 2036 includes an input connected to an output of the true differential receiver 2042 and an output connected to the bidirectional signal interface 2032. The quasi differential receiver 2038 includes an input connected to the bidirectional signal interface 2032 and an output connected to the true differential transmitter 2040. The true differential transmitter 2040 has the input connected to the output of the quasi differential transmitter 2036 and an output connected to the bidirectional signal interface 2034. The true differential receiver 2042 includes an input connected to the bidirectional signal interface 2034 and the output connected to the quasi differential receiver 2038. The clock transceiver 2010 includes bidirectional signal interfaces 2044 and 2046 connected to the pin interfaces of the cable receptacle interface 2006 associated with the clock signals CLK⁺ and CLK⁻, respectively, and bidirectional signal interfaces 2048 and 2050 connected to the corresponding conductive interconnects (e.g., cable wires) of the cable body 2007 used for transmitting clock signal components between the ends 2002 and 2004.

In the depicted example, the bidirectional circuit component 2008 operates in either a cable-transmit mode or a cable-receive mode based on the state of the direction signals direction signals 2012 and 2014. As used herein, the cable-transmit mode refers to the transmission of signals from the corresponding receptacle interface 2006 to the other side via the cable body 2007 and the cable-receive mode refers to the transmission of signals from the cable body 2007 to the corresponding receptacle interface 2006. Further, when the bidirectional circuit component 2008 of side 2002 is in one mode, the bidirectional circuit component 2008 of side 2002 is in the other mode so that one of the bidirectional circuit component 2008 is in cable-transmit mode and the other is in cable-receive mode.

In the cable-transmit mode, the bidirectional circuit component 2008 is configured to receive the signal Q₁⁺ from the cable receptacle interface 2006 via a switch component (not shown), process the signal Q₁⁺ using one or more active signal management processes to generate the signal T₁⁺, and provide the signal T₁⁺ for transmission to the other side via the corresponding conductive interconnect of the cable body 2007. Accordingly, in the cable transmit mode, the quasi differential receiver 2038 and the true differential transmitter 2040 are enabled, whereas the quasi differential transmitter 2036 and the true differential receiver 2042 are disabled. Accordingly, the switch component connects the quasi differential receiver 2038 to the cable receptacle interface 2006 to receive the signal Q₁⁺ from the cable receptacle interface 2006. The bidirectional circuit component 2008 applies one or more active signal management processes to the received signal Q₁⁺ and provides the resulting processed signal to the true differential transmitter 2040, whereupon the signal is converted to a true differential signal component (if not already in true differential form) and provided for transmission via the cable body 2007 to the other bidirectional circuit component 2008 at the other end of the cable.

In the cable-receive mode, the bidirectional circuit component 2008 is configured to receive the signal T₁⁺ from the cable body 2007, process the signal T₁⁺ using one or more active signal management processes to generate the recovered signal Q₁⁺, and provide the recovered signal Q₁⁺ to the corresponding pin interface of the cable receptacle interface 2006 for provision to the destination device to which the cable receptacle interface 2006 is connected while in cable receive mode. Accordingly, in the cable receive mode, the true differential receiver 2042 and the quasi differential transmitter 2036 are enabled, whereas the quasi differential receiver 2038 and the true differential transmitter 2040 are disabled. Accordingly, the true differential receiver 2042 receives the signal T₁⁺ from the cable body 2007. The bidirectional circuit component 2008 applies one or more active signal management processes to the received signal T₁⁺ and provides the resulting recovered signal to the quasi differential transmitter 2036, whereupon the signal is converted to a quasi differential signal component (if not already in form) and provided as recovered signal Q₁⁺ to the corresponding pin receptacle of the cable receptacle interface 2006 for provision to the destination device.

In a similar manner, the clock transceiver 2010 operates in two modes. In the first mode (associated with the cable-transmit mode at the same end), the clock transceiver 2010 receives clock signals CLK⁺ and CLK⁻ from the receptacle interface 2006 via the bidirectional signal interfaces 2044 and 2046, applies one or more active signal processes, such as clock encoding, to generate corresponding encoded clock signal ENC_CLK+ and its complement ENC_CLK−, whereupon the encoded clock signal ENC_CLK+ and its complement ENC_CLK− are provided to the corresponding conductive interconnects of the cable body 2007 for transmission to the clock transceiver 2010 at the other end. In the second mode (associated with the cable-receive mode at the same end), the clock transceiver 2010 receives encoded clock signals ENC_CLK+ and ENC_CLK− via bidirectional signal interfaces 2048 and 2050, respectively, applies one or more active signal management processes to a recovered differential clock signal represented by recovered signals CLK+ and CLK−, and provides the recovered signals CLK+ and CLK− to the corresponding pin receptacles of the cable receptacle interface 2006 via bidirectional signal interfaces 2044 and 2046 for provision to the destination device.

Thus, as illustrated by FIG. 20, the ends 2002 and 2004 of the bidirectional active signal management system 2000 can be respectively auto-configured as either a receiver of signals or a transmitter of signals, thereby allowing either end to be connected to a source device, and thus either end also can be connected to a destination device. Further, it will be appreciated that the cable adaptors discussed herein also can use the bidirectional techniques described herein so that each receptacle interface can be similarly configured to be bidirectional.

Referring to FIG. 21, an implementation of the bidirectional circuit component 2008, the direction detection module 2012, and the clock transceiver 2010 (herein, the collectively referred to as the bidirectional circuitry 2100) of FIG. 20 is illustrated in accordance with at least one embodiment of the present disclosure. In the depicted example, the bidirectional circuitry 2100 includes quasi differential circuitry 2102 including the quasi differential transmitter 2036 and the quasi differential receiver 2038 and true differential circuitry 2104 including the true differential transmitter 2040 and the true differential receiver 2042 as described with respect to FIG. 20. The bidirectional circuitry 2100 further includes shift registers 2105 and 2106, and a switch component comprising, for example, a multiplexer 2106 and a multiplexer 2108. The shift register 2105 includes an input connected to the output of the quasi differential receiver 2038 and an output, and the shift register 2106 includes an input connected to the output of the true differential receiver 2042 and an output. The multiplexer 2106 includes a first input connected to the output of the quasi differential receiver 2038 via the output of the shift register 2105, a second input connected to the output of the true differential receiver 2042 via the shift register 2106, and an output connected to an input of a signal processing path 2110 that implements active signal management circuitry, whereby the first input or the second input is selective couplable to the output based on the direction signal 2014. The multiplexer 2108 includes an input connected to an output of the signal processing path 2112, whereby the input is selectively couplable to one of a first output or a second output based on the direction signal 2014. The first output is connected to the input of the quasi differential transmitter 2036 and the second output is connected to the input of the true differential transmitter 2040.

The signal processing path 2110 includes one or more active signal management techniques to the digital signal output by the multiplexer 2106 and provide the resulting processed signal to the multiplexer 2108. Accordingly, when the bidirectional circuitry 2100 is configured to be in cable-transmission mode (as indicated by a first state for the direction signal 2014), the quasi differential receiver 2038 receives a signal Q₁+ from the bidirectional signal interface 2032 and provides it (or a processed representation) to the multiplexer 2106, which is configured by the directional signal 2014 to provide the signal Q₁+ to the signal processing path 2110, whereupon one or more active signal management processes (as well as other processes) can be applied to the signal Q₁+. The resulting processed signal is provided to the input of the multiplexer 2108, which is configured by the direction signal 2014 in the cable-transmit mode to provide the processed signal from its input to the true differential transmitter 2042 for transmission as signal T₁+ via a cable wire 2110 to the other side of the cable.

Conversely, when the bidirectional circuitry 2100 is configured to be in cable-receive mode (as indicated by a second state for the directional signal 2014), the true differential receiver 2042 receives a signal T₁+ from the cable wire 2110 and provides the signal T₁+ to the multiplexer 2106, which is configured by the directional signal 2014 to provide the signal T₁+ to the signal processing path 2110, whereupon one or more active signal management processes (as well as other processes), can be applied to the signal T₁+. The resulting processed signal is provided to the input of the multiplexer 2108, which is configured by the direction signal 2014 in the cable receive mode to provide the processed signal from its input to the quasi differential transmitter 2036 for transmission as signal Q₁+ to the destination device.

Referring to FIG. 22, an implementation of the direction detection module 2012 is illustrated in accordance with at least one embodiment of the present disclosure. It will be appreciated that in many implementations, the source device provides a clock signal used by the destination device for timing purposes. Accordingly, in one embodiment, the source of the clock signal is used to determine the direction of the data flow (i.e., which side is connected to the source device and which side is connected to the destination device). In the depicted example of FIG. 22, the direction detection module 2012 includes a counter 2202 having a clock input 2204 connected to a signal pin of the corresponding cable receptacle interface 2006 (FIG. 20) (e.g., a pin associated with either of the signal CLK+ or the signal CLK−), an input to receive a power on reset (POR) signal 2206 and an output to configure the direction signal 2014 to have the first state or the second state based on a comparison of the count of the counter 2202 to a predetermined count (e.g., zero for an implementation of the counter 2202 as a count-down counter or a predetermined non-zero number for an implementation of the counter 2202 as an incrementing counter). For purposes of discussion, it is assumed that the counter 2202 is a count-down counter in the example of FIG. 21. The illustrated example also includes a pull-down resistor 2208 to drive the direction signal 2014 to a low value (e.g., GND) when the output of the counter 2202 is not asserted.

When cable end is connected to a corresponding device, the application of power results in the assertion of the POR signal 2206, which causes the counter 2202 to reset and load a predetermined value into its count register. In the event that the cable end is connected to the source device, a clock signal is received at the clock input 2204 and the counter 2202 decrements in response to each cycle of the clock. In the event that the counter reaches zero in response to a corresponding number of cycles of the clock signal (and thereby allowing any bounce on the clock signal to subside), the direction signal 2014 is configured to have the first state (e.g., an asserted state), thereby indicating that the cable end is connected to the source device and thereby configuring the operation of the corresponding active signal management circuitry 2008 and the clock transceiver 2010 (FIG. 20), as described herein. Otherwise, if the cable end is connected to the destination device, no clock signal will appear at the clock input 2204, so the counter 2202 does not reach a zero count and the output of the counter 2202, and thus the direction signal 2014, remains in the second state (e.g., an unasserted state).

Although FIG. 22 illustrates a particular technique for determining which cable end is connected to which device, it will be appreciated that other techniques may be implemented without departing from the scope of the present disclosure. To illustrate, in one embodiment, the source device, or alternately the destination device, may configure a specific pin to have a particular state (e.g., asserted or unasserted) while the other device does not. In this instance, the assertion or unassertion of this specific pin can be used to identify the direction of data flow across a cable interconnect.

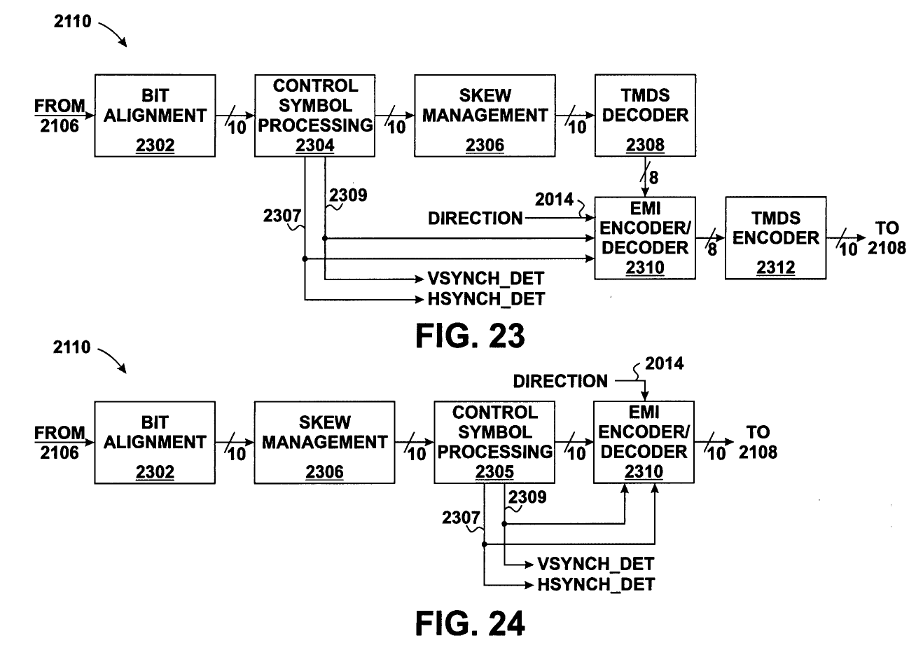

Referring to FIG. 23, an implementation of the signal processing path 2110 (FIG. 21) is illustrated in accordance with at least one embodiment. Although the illustrated example is described in the context of HDMI/DVI, it will be appreciated that the described implementation may be configured for other contexts as appropriate without departing from the scope of the present disclosure. Further, the illustrated implementation also may be used in the unidirectional implementations described herein.

In the illustrated example of FIG. 23, the signal processing path 2110 is utilized to process data transmitted over one of the data paths for a DVI/HDMI application, where the data provided by the source device is TMDS encoded and the destination device expects to receive TMDS-encoded data. As will be appreciated, TMDS encoding typically entails mapping an eight-bit value into a corresponding 10-bit TMDS-encoded value so as to reduce signal transitions, and TMDS decoding conversely entails mapping the 10-bit TMDS encoded value back to the original eight-bit value. Accordingly, in order to be compatible with standard DVI/HDMI configurations where TMDS-encoded data is provided to the cable interconnect and TMDS-encoded data is expected to be received from the cable interconnect, the signal processing path 2110 of FIG. 23 is configured to receive TMDS-encoded data and provide TMDS-encoded data.

The signal processing path 2110 of FIG. 23 includes a bit alignment module 2302, a skew management module 2306, a control (CTL) symbol processing module 2306, a TMDS decoder 2308, an EMI encoder/decoder 2310 and a TMDS encoder 2312. The bit alignment module 2302 includes an input to receive the contents of one of the shift register 2105 or the shifter register 2107, depending on the direction signal 2014, and an output to provide a bit-aligned 10-bit TMDS-encoded symbol value. The control symbol processing module 2304 includes an input to receive the bit-aligned symbol value and to detect whether the symbol value is a control symbol, such as a HSYNC or a VSYNC control symbol. In the event that the symbol value is determined to be a HSYNC control symbol, the control symbol processing module 2304 asserts a HSYNC_DET signal 2307. Likewise, the control symbol processing module 2304 asserts a VSYNC_DET signal 2309 when the control symbol processing module 2304 determines that the symbol represents a VSYNC control symbol. In certain implementations, such as DVI and HDMI, the control symbols have an established transition density that is designed to be different than all other symbols. In this case, the control symbol processing module 2304 can include a 1's/0's counter and comparator to determine the number of transitions, or a plurality of discrete symbol decoders (e.g., a unique 10-bit subtractor for each control symbol) to identify control symbols. In at least one embodiment, the control symbols are used to control FIFO synchronization and interchannel skew management.

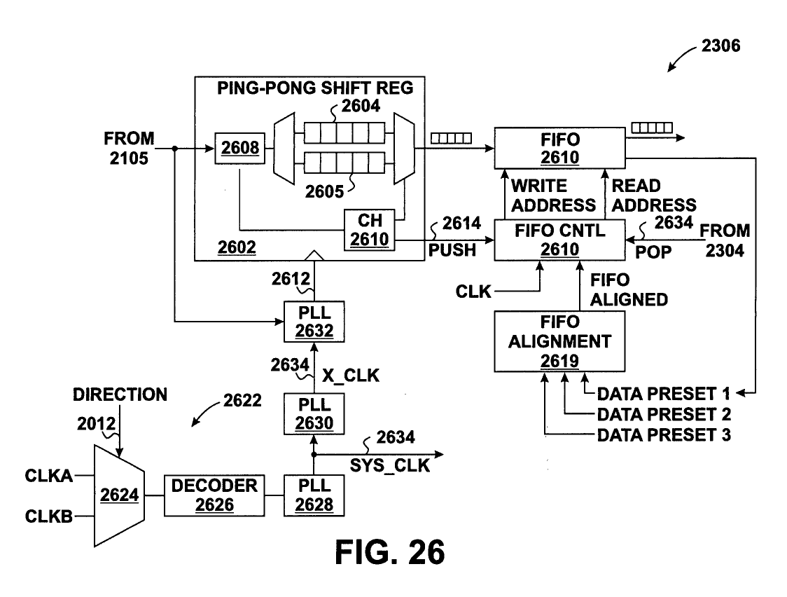

The skew management module 2306 includes an input to receive and buffer symbol values from the control symbol processing module 2304 and an output to sequentially provide buffered symbol values in response to one or both of the HSYNC_DET signal 2307 and the VSYNC_DET signal 2309. As described in greater detail herein with reference to FIG. 26, the skew management module 2306 reduces or minimizes skew between data paths, thereby reducing EMI due to intra-pair skew and/or improving transmitted signal fidelity.

The TMDS decoder 2308 includes an input to receive 10-bit TMDS encoded symbol values from the skew management module 2306 and an output to provide the corresponding 8-bit TMDS-decoded symbol value. The EMI encoder/decoder 230 includes an input to receive the 8-bit TMDS-decoded symbol value, an input to receive the direction signal 2014, and an output. In the event that the direction signal 2014 indicates that the signal processing path 2110 is at the transmit side, the 8-bit TMDS-decoded symbol value has not been EMI encoded and therefore the EMI encoder/decoder 2310 is configured to encode the 8-bit TMDS-decoded symbol value to generate an 8-bit EMI-encoded symbol value for transmission over the cable interconnect. Conversely, if the direction signal 2014 indicates that the signal processing path 2110 is at the receive side, the 8-bit TMDS-decoded symbol value provided by the TMDS decoder 2308 was also EMI encoded, and the EMI encoder/decoder 2310 therefore is configured to decode the 8-bit EMI-encoded symbol value to generate an 8-bit EMI-decoded symbol value. The resulting 8-bit symbol value, whether EMI-encoded or EMI-decoded, is provided to the TMDS encoder 2312, whereupon it is TMDS encoded to the corresponding 10-bit TMDS value and provided the multiplexer 2108 (FIG. 21) for processing by either the quasi differential transmitter 2036 or the true differential transmitter 2042, depending on whether the signal processing path 2110 is at the transmit side or the receive side of the cable interconnect.

As noted above, the signal processing path 2110 is configured to operate both at the transmit side of a cable interconnect or at the receive side of a cable interconnect. In instances where the signal processing path 2110 is at the transmit side, the raw digital input provided by one of the quasi differential receiver 2038 (via the shift register 2106) is provided to the bit alignment module 2302. However, it will be appreciated that this raw digital input typically is not bit aligned. Accordingly, the bit alignment module 2302 detects the proper bit alignment for the incoming raw digital signal and parses the raw digital signal into symbols based on this bit alignment. The parsed symbol values provided to the control symbol processing module 2305. Because the parsed symbol values are not EMI-encoded at the transmit side, the control symbol processing module 2305 analyzes each incoming symbol to determine whether it is a control (e.g., HSYNC/VSYNC) symbol as described above. After analysis, the symbol is provided to the skew management module 2306 for buffering so as to prevent skew mismatch between each of the data processing paths. After buffering, the symbol is TMDS decoded by the TMDS decoder 2308 and the resulting TMDS-decoded symbol value is EMI-encoded by the EMI encoder/decoder 2310.

It should be noted that CTL/sync period symbols are encoded differently from the normal active video symbols in many implementations, such as DVI and HDMI which provide for four different CTL symbols. Upon receipt of a TMDS symbol, the TMDS decoder 2308 compares a 10-bit value with the four valid CTL symbols. If a match is detected, the TMDS decoder 2308 randomly selects and outputs one of the four valid CTL symbols. If another symbol is encountered, it is processed (encoded) normally. The resulting EMI-encoded symbol value is then TMDS encoded by the TMDS encoder 2312 and provided for transmission to the receive side of the cable interconnect via the multiplexer 2108 and the true differential transmitter 2040 (FIG. 21).

In instances where the signal processing path 2110 of FIG. 23 is on the receive side, the input data stream is TMDS-encoded and EMI-encoded by the corresponding signal processing path at the transmit side. Accordingly, the received digital stream is bit aligned and parsed by the bit alignment module 2302 and the control symbol processing module 2304 passes the symbols to the skew management module 2306 for skew buffering in response to detected control symbols. The buffered symbols are sequentially output to the TMDS decoder 2308, which TMDS decodes each symbol value and provides the TMDS-decoded symbol value to the EMI encoder/decoder 2310 for EMI decoding. The resulting TMDS-decoded, EMI-decoded symbol value is then TMDS encoded by the TMDS encoder 2312 for provision to a source device via the multiplexer 2108 and the quasi differential transmitter 2036 (FIG. 21). It will be appreciated, that in cases where bidirectionality is not required, it the illustrated system can be implemented without the multiplexers to swap signal direction and without the direction detection circuits.

Referring to FIG. 24, an alternate implementation of the signal processing path 2110 of FIG. 21 is illustrated in accordance with at least one embodiment of the present disclosure. As with the implementation of FIG. 23, the implementation of FIG. 24 is illustrated in the context of a DVI/HDMI application whereby TMDS-encoded data is provided by a source device and TMDS-encoded data is expected by the destination device. However, in contrast to the implementation of FIG. 23 where the data was TMDS-decoded and then reencoded, the implementation of FIG. 24 does not access the underlying TMDS-encoded data.

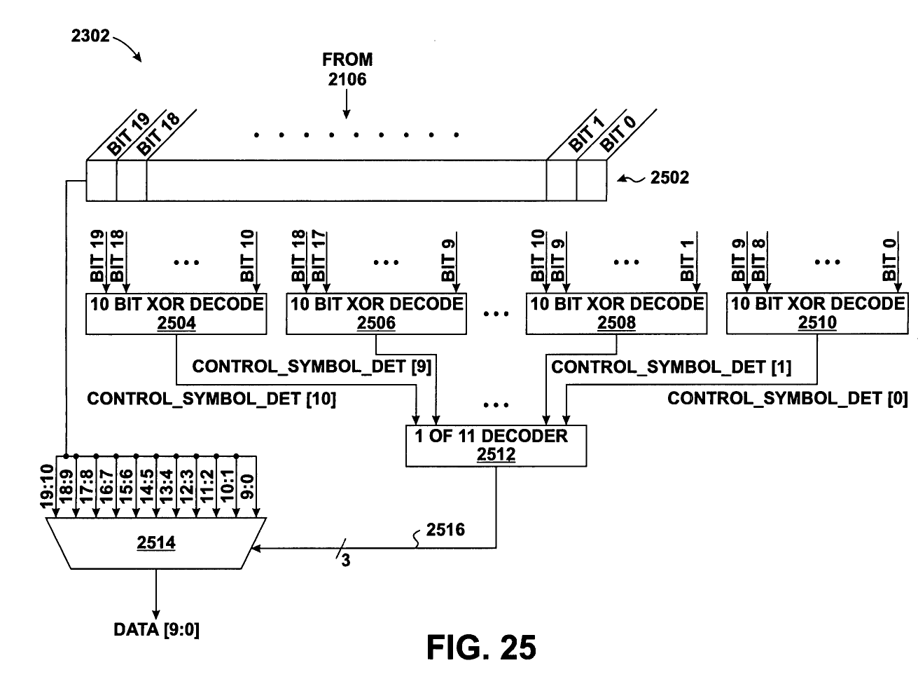

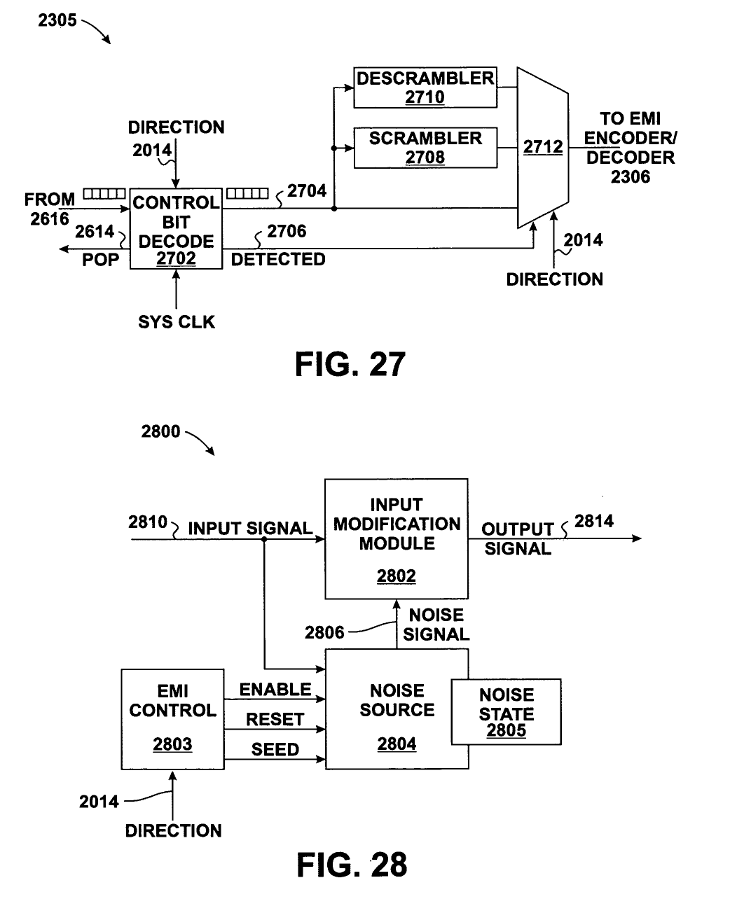

As illustrated by the embodiment of FIG. 24, the signal processing path 2110 includes the bit alignment module 2302, the skew management module 2306, a control symbol processing module 2305 (similar to the control symbol processing module 2304) and the EMI encoder/decoder 2310. In instances where the signal processing path 2110 is at the transmit side, the bit alignment module 2302 determines the proper bit alignment and parses the raw digital stream from the multiplexer 2106 accordingly. Because the incoming 10-bit symbols may be EMI encoded, it may be complicated to determine if the symbol is a valid CTL symbol prior to passing the 10-bit TMDS encoded and EMI encoded symbol to the skew management module 2306. Accordingly, the bit alignment module 2302, in one embodiment, checks for EMI-encoded CTL symbols in the incoming data signal as discussed in greater detail with reference to FIG. 25. In the event that the bit alignment module 2301 or the control symbol processing module 2304 detect a HSYNC control symbol, the HSYNC_DET signal 2307 is asserted. Likewise, if a VSYNC control symbol is detected, the VSYNC_DET signal 2309 is asserted. The control symbol processing module 2305 is illustrated in greater detail herein with reference to FIG. 27. The control symbol processing module 2304 then passes the 10-bit symbol value to the EMI encoder/decoder 230, which EMI encodes the 10-bit symbol value and provides the EMI-encoded symbol value to the true differential transmitter 2042 via the multiplexer 2108 (FIG. 21) for transmission to the receive side of the cable interconnect. It should be appreciated that the EMI encoder/decoder can detect minimum transition densities after EMI encoding, and can multiplex the original symbol back into the data path to help maintain DC balance in the interconnect.

In instances where the signal processing path 2110 of FIG. 24 is at the receive side of a cable interconnect, the incoming data is processed by the bit alignment module 2302, the skew management module 2306, and the control symbol processing module 2305 as discussed above. However, as the received data was EMI-encoded at the transmit side, the EMI encoder/decoder, in these instances, is configured by the direction signal 2014 to EMI decode the stream of symbol values into a stream of EMI-decoded symbol values for transmission to the source device via the multiplexer 2108 and the quasi differential transmitter 2036 (FIG. 21).

Referring to FIG. 25, an implementation of the bit alignment module 2302 is illustrated in accordance with at least one embodiment of the present disclosure. In the depicted example, the bit alignment module 2302 includes a 20-bit shift register 2502, a plurality of 10-bit XOR decoders, such as XOR decoders 2504, 2506, 2508, and 2510, a 1-of-11 decoder 2512, and a multiplexer 2514. Each the 10-bit XOR decoders includes an input to receive a corresponding 10-bit portion of the 20-bit raw value (raw_data[19:0]) stored in the shift register 2502 and an output to assert a corresponding control_symbol det[X] signal if a control symbol is detected in the corresponding 10-bit portion. To illustrate, the XOR decoder 2504 receives bits 19-10 of the raw data (i.e., raw_data[19:10]) and provides the control_symbol det[10] signal, the XOR decoder 2506 receives bits 18-9 of the raw data (i.e., raw_data[18:9]) and provides the control_symbol det[9] signal, the XOR decoder 2508 receives bits 10-1 of the raw data (i.e., raw_data[10:1]) and provides the control_symbol det[1] signal, the XOR decoder 2508 receives bits 9-0 of the raw data (i.e., raw_data[9:0]) and provides the control_symbol det[0] signal, and so forth. In operation, each of the XOR decoders analyzes its 10-bit input to determine if the 10-bit input represents a 10-bit TMDS encoded control symbol, such as a TMDS-encoded HSYNC symbol or VSYNC symbol. To illustrate, in DVI and HDMI, there are only four different control symbols, so each XOR decoder can be hard coded to XOR a specified bit sequence with its corresponding 10-bit symbol (e.g., by performing an XOR of the bit sequence “1010101011” with the incoming 10-bit symbol, whereby if the result is entirely zero's, then the 10-bit symbol is identified as an DVI/HDMI control symbol.”) Alternately, each bit can be XORed with the preceding bit (e.g., XOR bit 10 with bit 9, XOR bit 8 with bit 7, etc.) and perform an AND operation for all of the XOR operations and if the result is a logic 1, then the symbol is identified as a DVI/HDMI control symbol (e.g., in DVI/HDMI, control symbols are the bit sequences “1010101011”, “1101010100”, “0010101011”, and “0101010100”. so there is at least four 10/01 transitions as well as either a 00 or 11. In yet another embodiment, incoming bit sequence is EMI encoded and the XOR decoders therefore each receive a digital noise signal synchronized to the noise signal at the transmitting end for the purpose of EMI decoding their corresponding 10-bit symbol.

The 1 of 11 decoder 2512 includes an input to receive each of the control_symbol_det[X] signals (collectively, control_symbol_det[10:0]) and an output to provide a 4-bit multiplex control signal 2516 indicating which of the control_symbol_det[X] signals is asserted. The multiplexer 2514 includes ten 10-bit inputs to receive each of the 10-bit portions of the shift register 2502, a control input to receive the 3-bit multiplex control signal 2516, and an output to provide a select one of the 10-bit portions as a parsed 10-bit symbol value (data[9:0]) based on the multiplex control signal 2516.

As will be appreciated, in DVI/HDMI applications, a control symbol is periodically transmitted in the communications between a source device and a destination device. In one embodiment, the presence of a control symbol is used to detect the bit-alignment of the incoming data stream. Accordingly, in operation, twenty bits of a received digital signal is input into the shift register 2502 from either the shift register 2105 or the shift register 2107 (FIG. 21), depending on the value of the direction signal 2014. After the twenty-bit value is loaded, each XOR decode module checks its corresponding 10-bit portion to determine whether the 10-bit portion represents a TMDS-encoded control symbol. If no control symbol is detected, the control_Symbol_det signals remain unasserted and the process begins again when for the next twenty bits of the received digital signal. Otherwise, if a control symbol is detected by one of the XOR decoder modules, the XOR decoder module having the control symbol asserts its corresponding control_Symbol_det signal and the 1-of-11 decoder 2512 controls the multiplexer 2514 so that the 10-bit portion of the register 2502 corresponding to the XOR decoder module with the detected control symbol is used to output the first 10-bit symbol value. As discussed below with reference to FIG. 26, the control_symbol_det signal is utilized to initiate the storage of symbols at a FIFO of the skew management module 2306. Those versed in the state of the art will recognize that any simple multi-bit comparator, a subtractor or the like can be used instead of the XOR decoding method described by comparing the 10 bit slice (raw_data[X+9:X] to a given value, or plurality of values. In the embodiment depicted by FIG. 24, these compared values are driven by the EMI encoder value, properly adjusted to the pipeline delay through the signal path to remove the EMI coding and reveal the original TMDS symbol. Subsequent processing is used to detect the plurality of CTL symbols.

Referring to FIG. 26, an implementation of the skew management module 2306 is illustrated in accordance with at least one embodiment of the present disclosure. As will be appreciated, DVI/HDMI applications, as well as other applications, utilize multiple parallel data paths for transmitting information from a source device to a destination device. However, due to the length of the cable interconnect connecting the source device ad the destination device, considerable skew may be present between the parallel paths, thereby potentially causing snow, or incorrect colors on the video screen, since the start of each horizontal line is synchronous to each other at the same point in time. Accordingly, the skew management module 2306 provides a technique to realign the transmitted signal to correct for any skew present between data paths.

In at least one embodiment, each data path implements a skew management module 2306 which coordinates with the skew management modules 2306 of the other data paths to align the transmission of data via the parallel data paths so as to reduce skew. In the depicted example, each skew management module 2306 includes a ping-pong shift register module 2602 including two ping-pong N-bit shift registers 2604 and 2606, a sampling circuit 2608 and a controller 2610. The number N of bits per register is based on the packetization of the incoming data signal. To illustrate, for DVI/HDMI, data is transmitted in ten bit packets and for LCD display controllers, the packets typically are seven bits. Accordingly, the shift registers 2604 and 2606 are ten bits wide in HDMI/DVI implementations and seven bits wide in LCD implementations. The sampling circuit 2608 samples the incoming data signal based on a sampling clock 2612 and shifts the resulting sampled bits into a selected one of the shift registers 2604 and 2606.

Once the appropriate number of bits have been shifted in to form a packet (ten bits for DVI/HDMI, seven bits for LCD) and in response to the control_symbol_det signal asserted by the bit alignment module 2302 (FIG. 25), the controller 2610 asserts a push signal 2614, which acts as a write clock, thereby causing the stored packet to be transferred from the selected shift register into a first-in, first-out buffer (FIFO) 2616 at a write address indicated by a FIFO controller 2618. Further, the falling edge of the push signal 2614 acts to switch shift registers for the next symbol so that no bits are lost due to register overflow.

Once a packet, or symbol, has been stored to the FIFO 2616, the FIFO control 2618 asserts a Data_Present signal (e.g., a Data_Present 1 signal) provided to a FIFO alignment module 2619, thereby indicating to the FIFO alignment module 2619 that there is data present in the FIFO 2616. Once each of the skew management module 2306 for each data path has asserted its Data_Present signal, the FIFO alignment module 2619 asserts a FIFO_aligned signal, thereby enabling the FIFO controller 2618 to begin outputting data from the corresponding FIFO 2616. As a result, the skew management modules 2306 buffer received data until each data path has data buffered, at which time the skew management modules 2306 can begin providing buffered data, thereby reducing intra-pair skew. Accordingly, in response to a pop signal 2620 (from the control symbol processing module 2304 or 2305 (FIGS. 23 and 24) and in response to the FIFO_aligned signal being asserted, the FIFO controller 2618 directs the output of the symbol at the read address of the FIFO to the control symbol processing module 2304.

In at least embodiment, the total depth of the FIFO 2616 is based on the cable length and inter-pair skew of the cable relative to the maximum bit rate of the incoming serial data stream. To illustrate, if a cable interconnect has a one nanosecond-per-meter (nS/m) interpair-skew and the cable interconnect is ten meters, there is an expected 10 nS of total inter-pair skew. Accordingly, if the data rate is, for example, one gigabyte-per-second (Gb/s) with ten bits per symbol, indicating each bit period is 1 nS, and the time to transmit a pixel is 10 nS, the FIFO depth should accommodate one pixel symbol (pixel) to permit sufficient skew compensation.

FIG. 26 further illustrates a clock tree 2622 for generating one or more clock signals utilized by the signal processing path 2110. The clock tree 262 includes a multiplexer 2624, a clock decoder 2626, a phase locked loop (PLL) 2628, a PLL 2630 and a delay locked loop (DLL) 2632. The multiplexer 2624 selects from CLKA and CLKB (which represent the pixel clock in the DVI/HDMI and LCD implementations discussed herein) depending on the direction signal 2012. The selected clock signal is provided to the clock decoder 2626 and decoded if the clock signal is in encoded form. The resulting decoded/unencoded clock signal is input to the PLL 2628, which captures the incoming clock and multiplies it by an integer amount, such as by ten for DVI/HDMI and by seven for LCD display controllers. The output of the PLL 2628 can serve as a system clock (SYS_CLK) 2634. Further, the output of the PLL 2628 is provided to the PLL 2630, which multiplies the clock by another amount and generates another clock signal 2636 (clock signal X_CLK), which is provided to one input of the DLL 2632. The DLL 2632 further includes another input to receive the data signal as a reference edge, thereby allowing the DLL 2632 to select an appropriate sampling clock 2612 to reduce or minimize sampling bit errors/bit error rate.

Referring to FIG. 27, an implementation of the control symbol processing module 2305 is illustrated in accordance with at least one embodiment of the present disclosure. In DVI/HDMI and other implementations, the data signal often includes control symbols, such as those represented by the horizontal and vertical synchronization signals, HSYNC and VSYNC, are control symbols that occur periodically in the data stream. The periodicity of these control symbols often results in significant spectral energy emitted by the data signal. Accordingly, in one embodiment, the control symbol processing module utilizing control symbol scrambling to effectively reduce the periodicity of control symbols present in a data signal.

In the depicted example, the control symbol processing module 2305 includes a control bit decode module 2702, a control symbol scrambler 2708, a control symbol descrambler 2710 and a multiplexer 2712. The control bit decode module 2702 includes an input connected to the output of the FIFO 2616 (FIG. 26), an input to receive the clock signal SYS_CLK (FIG. 26), an input to receive the direction signal 2014, an output to provide the pop signal 2614 (FIG. 26), an output 2704 to provide symbols received from the FIFO 2616 after analysis, and an output to provide a control symbol detected signal 2706. The control symbol scrambler 2708 includes an input to receive a symbol at the output 2704 and an output to provide a scrambled representation of the symbol (scrambled symbol). The control symbol descrambler 27010 includes an input to receive the symbol at the output 2704 and an output to provide a descrambled representation of the symbol (descrambled symbol), such as an XOR operation using a digital noise signal synchronized to the digital noise signal used to scramble or otherwise encode the symbol. As another example, for control symbols descrambling can include XORing two CTL decode bits with any two bits of a digital noise signal, as long as it's the same two bits on both the transmit side and receive side. The multiplexer 2712 includes a first input connected to the output 2704, a second input connected to the output of the control symbol scrambler 2708, and a third input connected to the output of the control symbol descrambler 2710. The multiplexer 2712 is configured to selectively connect one of the first, second or third input to its output based on the direction signal 2014 and the control symbol detected signal 2706. The output of the multiplexer 2712 is provided to the EMI encoder/decoder 2310 (FIG. 23).

At a rate determined by the clock signal SYS_CLK (determined from a pixel clock, for example), the control bit decoder 2702 asserts the pop signal 2614 and receives the resulting symbol from the FIFO 2616. The control bit decoder 2702 then provides the symbol to the output 2702, whereupon it is scrambled by the control symbol scrambler 2708 and descrambled by the descrambler 2710 in parallel. While the scrambling/descrambling processes are performed, the control bit decode module 2702 determines whether the packet represents a periodic control symbol. The control bit decode module 2702 can make this determination by, for example, comparing the symbol with known values for control symbols in both their unscrambled and scrambled form. In the event of a match with an unscrambled control symbol or a scrambled control symbol, the control symbol detected signal 2706 is asserted. Otherwise, if no periodic control symbol is detected, the control symbol detected signal 2706 remains unasserted.

If the direction signal 2014 indicates a cable-transmit mode and the control symbol detected signal 2706 is asserted (i.e., a periodic control symbol was detected), the scrambled symbol is selected by the multiplexer 2712 for provision to the EMI encoder/decoder 2306, thereby in effect providing an encoded or scrambled representation of the periodic control symbol, thereby reducing its effective periodicity. If the direction signal 2014 indicates a cable-receive mode and the control symbol detected signal 2706 is asserted (i.e., a periodic control symbol was detected), the descrambled symbol is selected by the multiplexer 2712 for provision to the EMI encoder/decoder 2306, thereby in effect recovering the control symbol that was scrambled at the transmit side for purposes of EMI reduction. In the event that the control symbol detected signal 2706 is unasserted (i.e., a periodic control symbol was not detected), the unmodified symbol at the output 2704 is selected by the multiplexer 2712 for provision to the EMI encoder/decoder 2306.

Referring to FIGS. 28-40, implementations of an EMI encoder/decoder for encoding or decoding a data signal or a clock signal are illustrated in accordance with at least one embodiment of the present disclosure. FIG. 28 illustrates one implementation of an EMI encoder/decoder 2800 according to one embodiment of the present disclosure. As seen in FIG. 28, the EMI encoder/decoder 2800 includes an input modification module 2802 and a noise source 2804. The noise source 2804 may include any of a variety of noise sources capable of providing a power spreading signal. Examples of the noise source include, but are not limited to, a pseudo-random digital noise generator (such as a linear feedback shift register or LFSR), a random digital noise generator, a polynomial generator, a quadratic residue code sequence generator or an elliptic curve generator. In another embodiment, noise source 2804 can be a Gaussian digital noise generator. Noise source 2804 may employ series of registers to produce a noise state to provide a binary stream to the input modification module 2802, as will be discussed in greater detail below.

In operation, an input signal 2810 is provided to the input modification module 2802. In instances where the input signal 2810 is a clock signal, the input signal 2810 may also be provided to noise source 2804 or a separate clock may be used to drive the noise source 2804, such as when the signal 101 is a data signal. The noise source 2804, in one embodiment, serves to generate a random sequence of noise states 2805 that are used to provide a power spreading digital noise signal 2806, generally comprising a binary data stream, for use by input modification module 2802 to facilitate producing an output signal 2814 from the input signal 2810. In instances where the EMI encoder/decoder 2800 is configured as an encoder, the input signal 2810 represents an unencoded signal and the output signal 2814 represents an EMI encoded signal. Conversely, where the EMI encoder/decoder 2800 is configured as a decoder, the input signal 2810 represents an EMI-encoded signal and the output signal 2814 represents an EMI-decoded, or unencoded, signal.

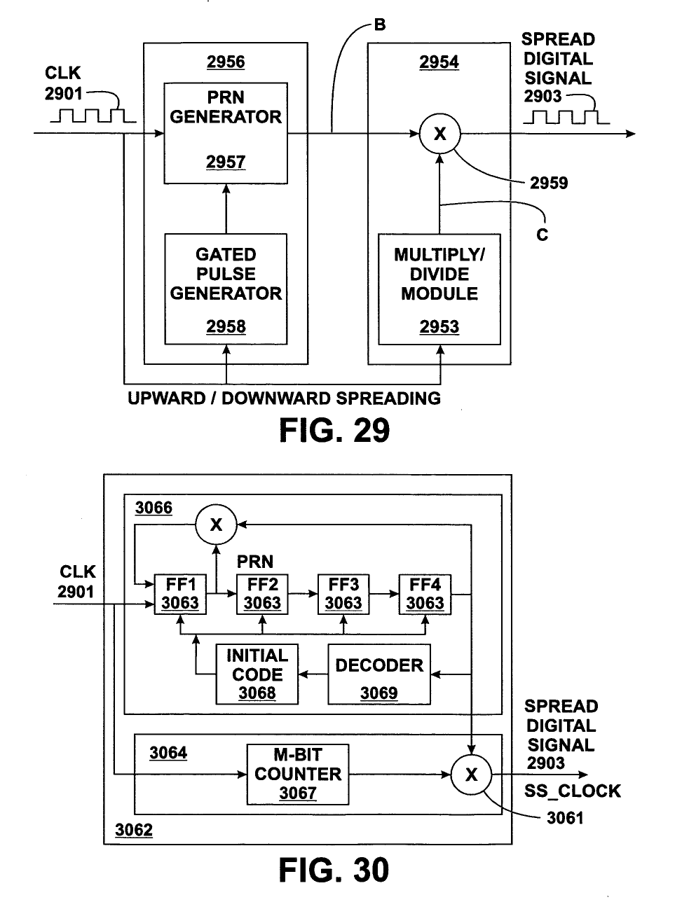

In one embodiment, noise source 2804 includes a look-up table. In another embodiment, noise source 2804 may be a linear feedback shift register (LFSR). In yet another embodiment, the look-up table access, or the state sequence of the LFSR can be gated, or controlled by logic to produce any desired number of repeating states, as further discussed with reference to FIG. 29. In one embodiment, the number of repeating states is selected to be an even number of states to facilitate the use of a phase locked loop (PLL) circuit having an even divider in its feedback loop, which is more readily implemented than odd dividers.

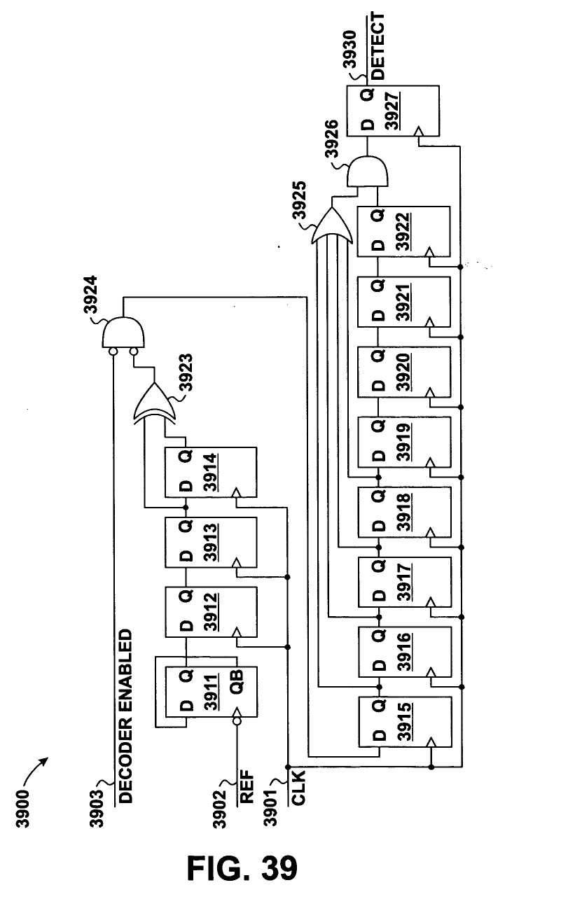

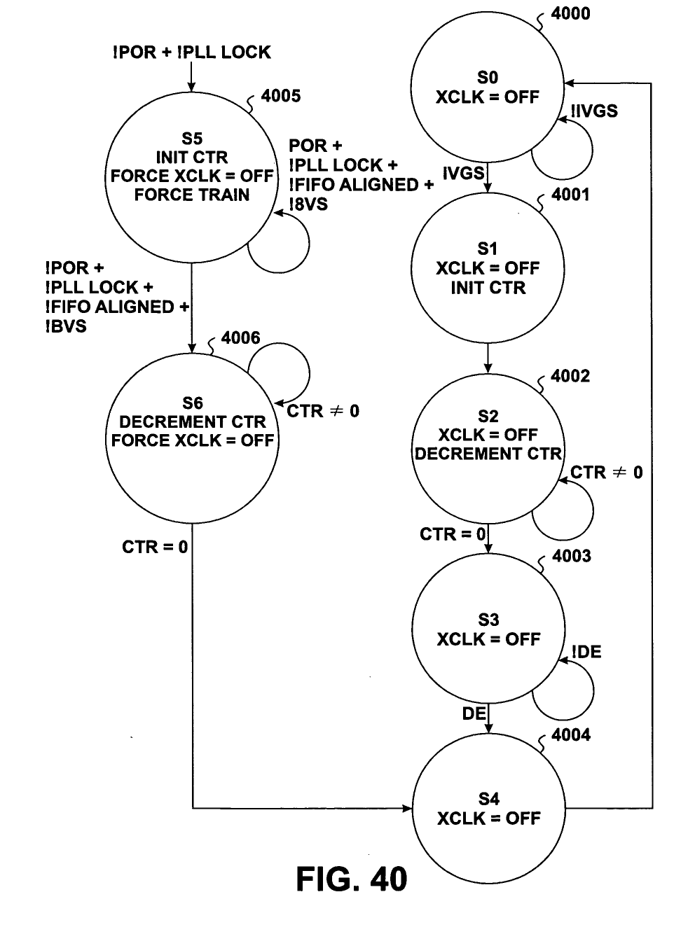

In one embodiment, the EMI encoder/decoder 2800 further includes an EMI controller 2803 having an input to receive the direction signal 2014 and outputs to provide, for example, an enable signal, a reset signal and a seed value for the noise source 2804. As discussed with greater detail herein with reference to FIGS. 39 and 40, the EMI controller 2804 can implement various synchronization features when the EMI encoder/decoder 2800 is configured to be an EMI decoder at the receive side of an interconnect. To illustrate, when in the input signal 2810 is a clock signal or other periodic signal, the EMI controller 2804 can implement logic to detect a change in the frequency of the input signal 2810 (FIG. 39) so that the EMI controller 2804 can reset the EMI encoder/decoder 2803 and other components so as to resynchronize to the new frequency. Further, the EMI controller 2804 can implement a periodic resynch technique (FIG. 40) so as to periodically resynchronize the EMI encoder/decoder 2800.

Referring to FIG. 29, an implementation of the noise source 2804 as a pseudo noise generator 2956 using a gated pseudo random number (PRN) generator 2957 is illustrated. For the illustrated example, it is assumed that the input signal 2810 (FIG. 28) is a clock (CLK) signal 2901. A gated pulse generator 2958 maintains a count or state based upon the number of pulses received at its input, while the PRN generator 2957 cycles through a sequence of states and outputs a random binary stream B based on these states. In response to receiving a predefined number of pulses, the gated pulse generator 2958 generates a reset signal to the PRN generator 2957, whereupon the PRN generator 2957 is reset or initialized to a starting value, and begins cycling through the sequence of states once again.

In one embodiment, the gated pulse generator 2958 resets the PRN generator 2957 to allow for an even number of states to be generated. The gated pulse generator 2958 can also be programmable so that the number of states in the sequence generated by the PRN generator 2957 is selectable by a system (e.g., application transmitters or system BIOS) or by a user (e.g. based on a program state or by an external pin). By varying the number of states associated with the PRN generator 2957, the degree of EMI reduction can be varied, as discussed herein.

Module 2954 is a more detailed embodiment of an input modification module, such as input modification module 2802. Module 2954 receives the CLK signal 2901 at a multiply/divide module 2953. In response, a clock pulse C is provided to the multiplier 2959 having a frequency component that can vary from the original CLK signal 2901. Below some multiplication value, e.g., 1, the clock pulse provided by multiply/divide module 2953 will produce a clock having a frequency component less than or equal to CLK signal 2901. Above the multiplication value, the clock pulse provided by multiply/divide module 2953 will produce a clock having a frequency component greater than or equal to the CLK signal 2901.

In this manner, the generated spread digital signal 2903 (e.g., the output signal 2814, FIG. 28) can be “up-spread” to frequencies higher than the original CLK signal 2901, or “down-spread” to frequencies lower than the original CLK signal 2901. By facilitating up-spreading and down-spreading, it is possible to move EMI emissions away from critical frequencies.

The clock pulse from multiply/divide module 2953 and the random binary stream from the PRN generator 2957 are combined by multiplier 2959 to produce the spread digital signal 2903. In one embodiment, the multiplier 2959 is implemented using an exclusive-OR (XOR) gate.

Referring to FIG. 30, an alternate embodiment of an EMI encoder portion 3062 of the EMI encoder/decoder 2800 of FIG. 28. In one embodiment, a code generator such as Maximum-Length Shift-Register sequence generator or M-sequence generator 3066 (implementations of a noise source), generates a random code 2M-1 states long, where M is the number of register stages 3063, flip-flops 3063 or storage elements 3063 within the encoder portion 3066. In another embodiment, the maximum-Length Shift Register sequence generator generates a random code with 2ˆM states in length by having the decoder 3069 decode the last state. For example, if four registers or flip-flops 3063 (M=4) are implemented, then the repeated sequence will complete and then begin to repeat itself after transmitting fifteen bits (e.g., 24-1 bits).

If four registers, e.g., flip-flops 3063 (M=4), are used and an even number of states are desired, then the decoder 3069 decodes the last state in the repeating sequence and inserts one additional initial state, such as the last state, to add an extra state to the sequence, therefore, repeating the sequence at 2M cycles instead of 2M−1 cycles, as is common with DSSS applications using CDMA communication.

It will be appreciated that a pseudo-random number generator, such as, for example, the Maximum-Length Shift-Register sequence generator or m-sequence generator 3066, generates a random code with 2ˆM−1 bits long, where M is the number of register stages with feedback connections. The initial code loaded to the registers 3063 is shifted to the left one bit at a time through a total of 2ˆM−1 sequential shifts to complete one pseudo-random bit stream cycle. The feedback circuits between the M elements in the register (which is often one or more XOR gates connected to one or more of the M flip flops 3063, input, and/or output of the circuit, and are not illustrated) ensures that the M bits change in state on each shift in order to transform the M bits into a 2ˆM−1 pseudo-random repeating bit stream. Therefore, the device will cycle through all possible 2M−1 serial stream bit states before beginning to repeat the sequence again. In essence, the shift register is shifted back to the original state or binary value within in the M bit device every 2ˆM−1 shifts. In practice, M may be any number and is usually a number greater than three.

Multiplier 3061 receives a pseudo random binary stream from the output of 74. A representation of CLK signal 2901 at a lower frequency is received from the M-bit counter 3067. The representation of the CLK signal 2901 at the output of the counter 3067 is combined with the pseudo random binary stream from module 3066 at the multiplier 3061 to generate the spread digital signal 2903.

Moreover, in at least one embodiment, the noise source 2804 may be configurable so as to facilitate the use different input codes for use in generation of a noise signal. To illustrate, the input of each of the M flip-flops 3063 may be connected to the output of a respective multiplexer, where each multiplexer has as inputs the output of the previous state or the output of the previous state XOR'd (or XNOR'd) with the most significant bit of the noise source. Thus, the noise signal, and thus the EMI signature, may be changed by programming the transmit power spreading module or writing a value to one or more registers, where the register values/programming determine the control inputs to the multiplexers. This technique therefore may reduce or eliminate the need to make manufacturing-based changes to the transmit power spreading module to utilize new or different noise signals. It will also be appreciated that the noise source of the receiver also may be similarly configurable.

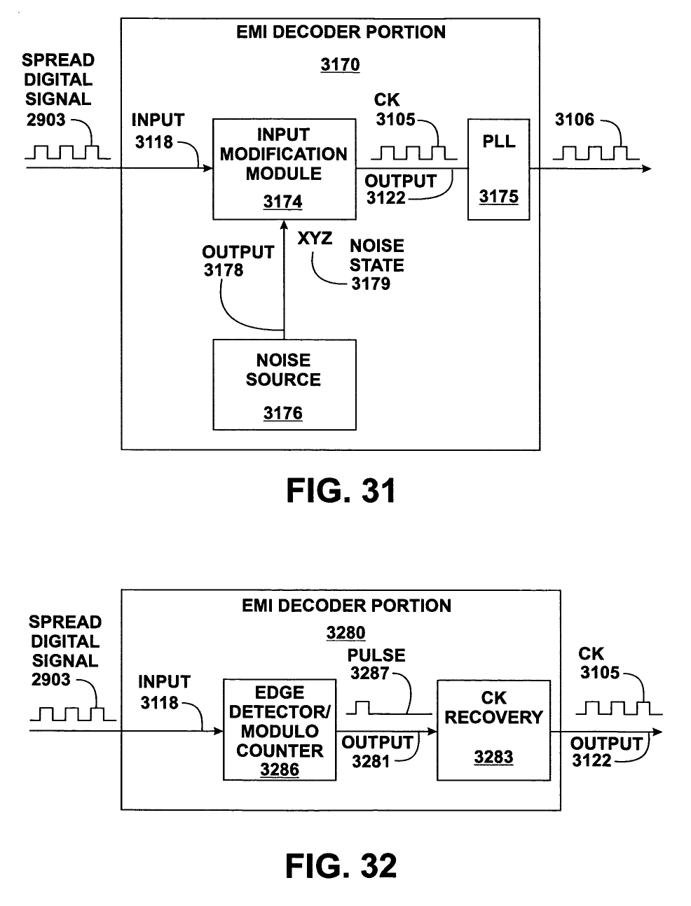

Referring to FIG. 31, an implementation of an EMI decoder portion 3170 of the EMI encoder/decoder 2800 of FIG. 28 is illustrated in accordance with at least one embodiment of the present disclosure. The EMI decoder portion 3170 includes an input modification module 3174 and a noise source 3176. In some implementations, the decoder portion of the EMI encoder/decoder portion at the receive side of an interconnect will have a priori knowledge of the encoder portion of the EMI encoder/decoder at the transmit side of the interconnect. Because of this a priori knowledge of the transmit-side encoding, the receive-side EMI decoder portion is informed of the exact noise source function implemented for encoding at the transmit side.

By implementing the identical noise source function in the noise source 3176 as was implemented at the transmit side of the interconnect, it is possible to recover the original signal, which was originally spread to produce the spread digital signal 2903. In addition, in the event that the signal represents a clock signal (e.g., a pixel clock), the resulting clock signal 3105 may be provided to a phase locked loop (PLL) 3175 in order to generate an output signal 3106 (e.g., a clock signal) that is synchronized to a known phase relationship with the original CLK signal 2901, by delaying the phase-locked loop feedback by an amount equivalent to an insertion delay, which includes the random number spreading signal.

The EMI decoder portion 3170 generates the clock signal 3105 in two steps. The first step is an acquisition step, during which synchronization to the spread clock/data signal 2903 is acquired. Acquisition is obtained by comparing the incoming bitstream with the power spreading signal of the noise source 3176 on a clock by clock basis. If a particular state, random number code, or noise state is found to be a match, then the process continues to determine if state N+1 is also valid, otherwise the first noise state is held. If state N passes, it continues to the next state until all states are verified. Otherwise the process continues with the first initial state. Therefore, by providing a noise source 3176 that generates the same noise states as the transmitting spreading module, it is possible to recover the original clock/data 101 in a manner that allows for synchronous system operation.

One advantage of the EMI decoder portion 3170 is that any noise induced upon the spread signal 2903 is also spread and added to the noise floor of the clock signal 105. As a result of this spreading, any noise impulses on the spread clock/data signal 2903 have little or no effect on the recovered clock signal 3105. This is advantageous, in that with synchronous systems, it is desirable for the same number of clock pulses to be the same at various points of the system. Therefore, by spreading the EMI noise on the spread clock/data signal 2903, the number of clock cycles received at the transmit power spreading module and the number of clock cycles produced by the EMI decoder portion 3170 can be maintained.

Referring to FIG. 32, yet another embodiment of a decoder portion 3280 of the EMI encoder/decoder 2800 of FIG. 28 is illustrated in accordance with at least one embodiment of the present disclosure. The EMI decoder portion 3280 receives the spread digital signal 2903 at an input 3118 coupled to an edge detector modular counter 3286. The edge detector/modulo counter 3286 interprets the information received on the spread digital signal 2903 to generate a pulse at its output 3281, which is used by a clock recovery module 3283 to regenerate the original CLK signal 2901 as clock signal 3105 on output 3122.

Specifically, the edge detector/modulo counter 3286 has a priori knowledge of the spread digital signal 2903 being received. As a result, the edge detector/modulo counter 3286 knows how many rising clock edges or falling clock edges the spread digital signal 2903 will have in its repeating sequence. For example, for a 2M sequence, where M is equal to 4, there will be a fixed number of clock transitions based upon the initial value with which the pseudo number generator was loaded. Therefore, the edge detector/modulo counter 3286 includes a counting mechanism that generates a pulse 3287 each time the spread digital signals 2903 count sequence repeats. For example, assuming for a value of M there are to be a total of twelve rising edges, the edge detector modular counter 3286 would generate a pulse 3287 at output 3281 every twelve clock edges.

The pulse generated at output 3281 is provided to the clock recovery module 3283 that includes a phase locked loop and a divide by N counter (not shown) in order to regenerate a representation of the original CLK signal 2901 illustrated as clock signal 3105 at output 3122. However, it will be appreciated that in a noisy environment where the spread digital signal 2903 can pickup EMI noise, the EMI noise may be interpreted as an additional rising edge which would result in the pulse 3287 at output 3281 being generated at an unexpected time. This should result in the clock signal 3105 not having a fixed frequency, thereby making it more difficult to implement in a synchronous system.

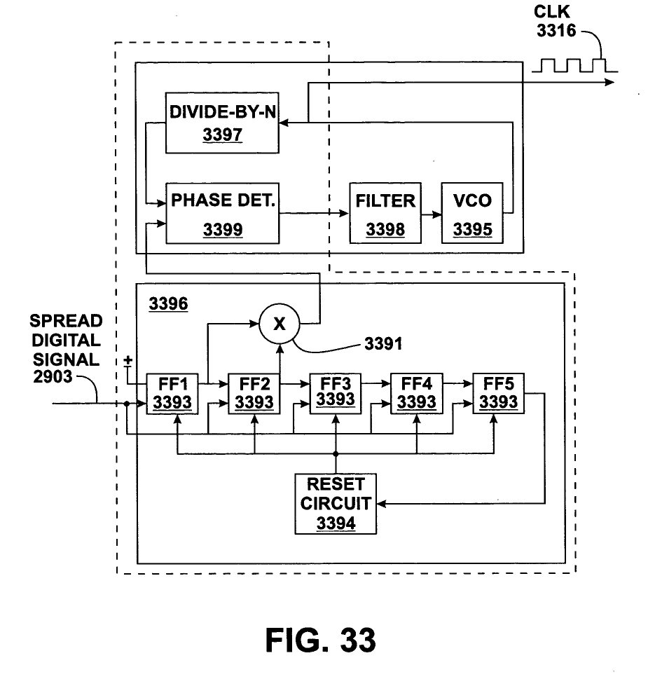

Referring to FIG. 33, a more detailed embodiment of EMI decoder portion 3280 of FIG. 32 is illustrated in accordance with at least one embodiment of the present disclosure. The module 3396 corresponds generally to the edge detector/modular counter 3286 of FIG. 32. Specifically, five flip-flops 3393 are connected serially with the last bit driving a reset circuit 3394. The reset circuit 3394 is in turn capable of resetting the series connected flip-flops 3393 (FF1-FF5) in order to begin a new count.

While it will be appreciated that many types of counters can be used, the counter illustrated in module 3396 operates by walking an asserted value along the flip-flop 3393 chain with each active edge of the spread digital signal 2903. For example, after a reset caused by reset circuit 3394, the values on the outputs of each of the flip-flops 3393 would be negated, i.e., zero. As a result, the multiplier 3391, which functionally is an exclusive-OR, will provide a low value at its output. Upon receiving a first active edge from the spread digital signal 2903, following reset, an asserted value, such as a logic level one, will be latched onto the output of the first flip-flop 71.

As a result of the output of the first flip-flop 71 being asserted, the exclusive-OR (XOR) function 3391, now receiving an asserted signal and a negated signal, provides an asserted signal at its output. Following a next active edge transition of the spread digital signal 2903, the asserted value at the output of the first flip-flop 71 will be latched into the output of the second flip-flop 72, as well as an asserted value being latched into the output of the first flip-flop 71. Since the exclusive-OR function 3391 has now received two asserted inputs, its output will be negated, where it will remain for the remainder of the counting sequence. The counting sequence will continue until the asserted signal is received at the output of the flip-flop five 75, whereby the reset circuit will reset each of the flip-flops 3393 that have negated values.

It will be appreciated that while the edge detector/modular counter 3396 has been described as being reset to a negated value on each of its outputs in one embodiment, it will be appreciated that in other embodiments the reset circuit could preload a specific value into the flip-flops 3393. In addition, while a simple bit walking counter has been implemented, other types of counters may be implemented.

In the manner described above, the XOR module 3391 generates the pulse 3287 (FIG. 32) which corresponds to the repeating of the spread digital signal 2903 sequence based upon an expected count. This pulse 3287 is provided to a phase detector 3399, which in turn provides its output to a filter 198 that in turn provides its output signal to a VCO 3295, which in turn provides its output signal to a divide by N counter 197 that is fed back to the phase detector 3399. In this manner, the clock recovery module 3283 (FIG. 32) can be implemented where the phase-locked loop stability is then is directly related to the relative duty cycle of incoming pulses to output clock frequency.

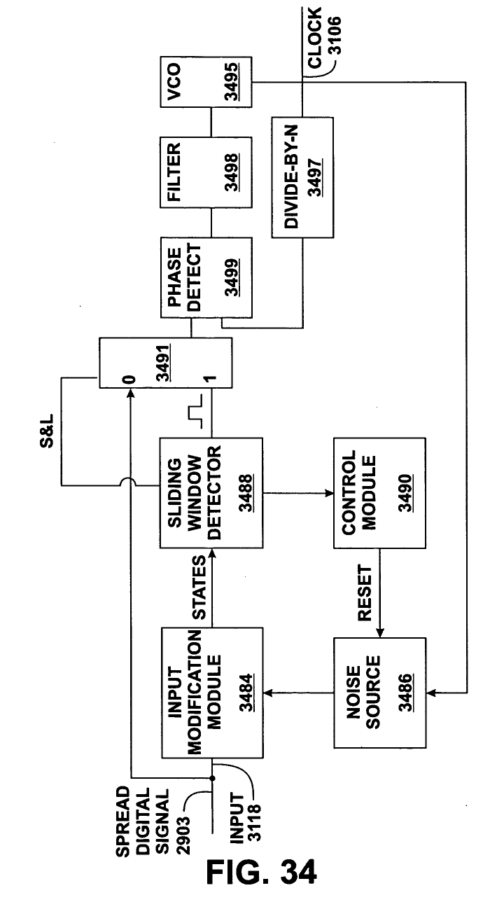

Referring to FIG. 34, another embodiment of an EMI decoder portion of the EMI encoder/decoder 2800 of FIG. 28 is illustrated in accordance with at least one embodiment of the present disclosure. In operation, the EMI decoder portion of FIG. 34 allows for the detection of a spread digital signal 2903, whereby when detected, the spread digital signal 2903 has its power re-spread in order to recover the original clock. However, when the presence of digital signal 2903 is not detected, it is assumed that the signal being received at the input 3118 of the input modification module 3484 is an un-spread digital clock signal, which is passed through the system instead of regenerating the spread digital signal 2903.

In order to describe the operation of the receive power spreading module of FIG. 34, it is assumed that the module is initially coming up from a reset state. When coming up from a reset state, the phase locked loop portion including VCO 3495 is designed to generate an output clock that reasonably approximates an original clock expected to be recovered from the spread digital signal 2903. This clock is provided to the noise source 3486 and any other modules needing control during the startup process.

As a result of the startup process, the control module 3490 holds the noise source 3486 at a specific state, which in turn provides a value to the input modification module 3484. For example, a logic one (1) can be provided to the input modification module 3484 during the acquisition phase. Since the receive power spreading module of FIG. 34 is anticipating a spread digital signal having a specific signature, during the reset portion the input modification module 3484 can receive the spread digital signal 2903, and, by using the startup clock generated by the VCO, latch a sequence of values for states corresponding to the received spread digital signal 2903.

It is these values or states, which can be provided to a sliding window detector 3488 to look for a predetermined sequence associated with the spread digital signal 2903. For example, the spread digital signal 2903 may have a sequence that repeats every 16 bits, however, the sliding window detector 3488 knows that there is a unique bit sequence that can be detected by monitoring only a subset of that total number of bits. Therefore, for example, only three or four bits may need to be observed at one time in order to ascertain whether or not the signal being received actually contains the signature of the spread digital signal 2903.

When the sliding window detector 3488 positively identifies the spread digital signal 2903 as being received, the control module 3490 is signaled and the noise source 3486 is taken out of reset and allowed to cycle through its states. In addition, the sliding window detector 3488 activates a select line to multiplier 3491 to allow the signal from the sliding window detector 3488 to be passed to the phase detector 3499 in order to allow the phase lock loop comprising the elements 3499, 3498, 3495, and 3497 to generate the clock 106, which is a representation of the original clock which was spread to generate the spread digital signal 2903. Note that in this embodiment, the sliding window detector 3488 may also need to provide a value to the divide by N counter 3497 indicating that the phase locked loop may have to multiply the pulse being detected.

Note that since the noise source 3486 is generating all the states and the input modification module 3484 is modifying all the signals being received from the spread digital signal 2903, that it would be possible for the input modification module to generate the clock 106 directly, and bypass the sliding window detector 3488 in order to provide the clock to the phase detector 3499 for clock acquisition. This clock can be generated to have a known phase relationship with the original CLK signal 2901, by delaying the phase-locked loop feedback by an amount equivalent to an insertion delay, which includes the random number spreading signal.

However, in another embodiment where the sliding window detector 3488 never detects the expected signature from the spread digital signal 2903, an assumption may be made that the signal being received at the input modification module 3484 is not a spread digital signal 2903, but an actual data or clock signal that should be passed through unaltered. In this case, the sliding window detector 3488 would signal the multiplier 3491 to pass the signal at its other input to the phase detector 3499. It will be appreciated when the clock being received at the input is to be passed through to the output of the EMI decoder portion, that the divide by N counter 3497 may need to be reprogrammed in order to allow the signal to pass through without modification.

Once advantage of implementing a receive power module of the type illustrated in FIG. 34, is that either a known spread signal can be re-spread in order to generate an expected clock, or, for situations where it is desirable not to use a spread signal, an ordinary clock can be used and passed through the device.

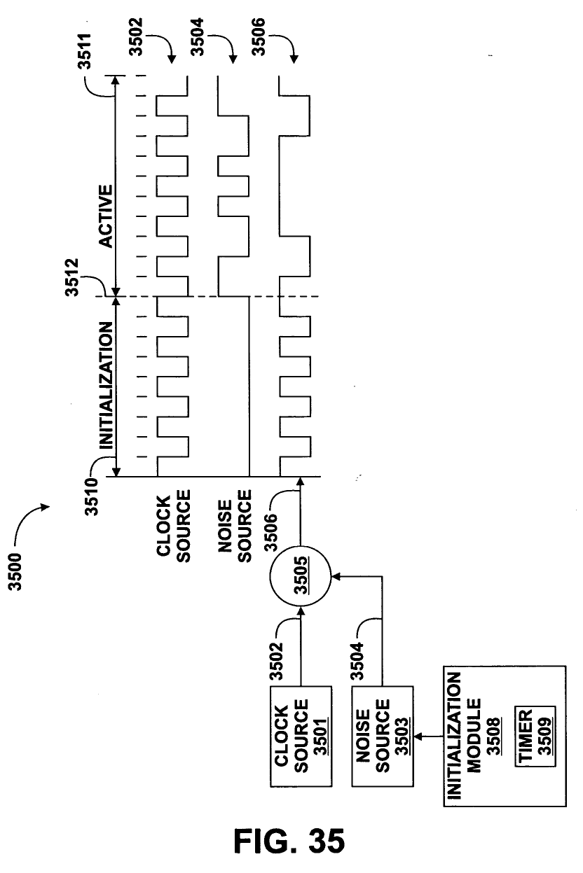

As described in detail above, the digital signals transmitted between a source device and a destination device may represent a digital clock signal (e.g., a pixel clock) to which a PLL or other clock synchronization device is synchronized. In a number of instances, the transmitted digital signal may transition from representing an unmodified digital clock signal (referred to herein as the “normal mode”) to representing a modified or encoded digital clock signal (referred to herein as the “XEMI mode”), or vice versa. FIGS. 35-38 illustrate a technique for identifying these transitions so as to properly synchronize a PLL or other clock synchronization device accordingly. As described in detail below, in one embodiment, after a phase lock is achieved with a non-spread clock, a timeout occurs which controls the transition to XEMI mode. The entry mode is made such that the most significant bit of the encoder of the transmitter is overridden so that a pattern that does not exist within the normal “states” of the noise source is created. This pattern facilitates the entry into XEMI mode in a predictable way so that if an impulse noise event, either on the transmission line or some noise inside the receiver, causes a mis-sample of the input clock to the receiver, a false entry into XEMI mode is precluded. If a mis-sample occurs without this feature, i.e., a noise event occurs which causes a clock edge to move in time (i.e., forward or reverse with respect to the normal edge placement of a clock with X amount of jitter) then the clock sampling circuit inside the receiver may perceive this as an “entry” into the XEMI mode, and start its noise source. At this point, the receiver clock typically is no longer locked to the incoming signal and the system may operate erroneously as a result. By using a particular pattern (such as holding the clock to a “1” state or a “0” state for several clock cycles), the receiver may ascertain that the transmitter is entering the XEMI mode. Accordingly, the first clock (which is out of phase because the receiver noise source would not yet be turned on) is suppressed with respect to the input to the phase frequency detector on a PLL to prevent the PLL from losing lock. Since this occurs only once upon entry and exit to the XEMI mode, there typically is minimal jitter impact for one clock, and because the system has not yet exited the power on reset state, no unexpected operations of the system are expected. One reason for the use of a unique state is that there typically is no control of whether multiple error events occur in the transmission of the clock and it therefore may be possible, though improbable, to cause a condition such that the receiver erroneously think multiple entry exits are occurring in the system.

FIG. 35 illustrates a clock transmitter 3500 (e.g., at the transmit side of an interconnect) having a clock source 3501 (e.g., the clock signal output of a source device) having an output to provide a digital clock signal 3502, a noise source 3503 to provide a power spreading signal 3504 and a signal modification module 3505 having an input to receive the digital clock signal 3502 and an input to receive the power spreading signal 3504 and an output to provide an encoded clock signal 3506 that represents the digital clock signal 3502 modified using the power spreading signal 3504. The transmitter 3500 further includes an initialization module 3508 having an output operably coupled to the noise source 3503 to control the operation of the noise source 3503.

As will be appreciated by those skilled in the art, a number of clock cycles typically are required before a PLL is synchronized to a clock signal and is stable. Thus, the immediate transition from an unmodified clock signal to a modified clock signal by the transmitter 3500 after, for example, power up may cause the PLL at the receive side of the interconnect to fail to properly lock to the clock signal or may cause an unstable lock by the PLL. Accordingly, in at least one embodiment, the initialization module 3508 provides a control signal to the noise source 3503 to maintain the noise source 3503 in an initialization state during an initialization stage 3510. During this initialization stage 3510, the output of the noise source 3504 preferably is held at a constant logic value (e.g., logic value “zero”) so that the clock signal 3502 is output in unmodified form as clock signal 3506. Thus, a receiver receiving the clock signal 3506 may synchronize its PLL to the clock signal 3506, which during the initialization period 3510 represents the unmodified clock signal 3502.

After the initialization period 3510, the PLL of at the receive side of the interconnect is expected to be synchronized to the unmodified clock signal 3502 and stable. The initialization module 3508 may time the initialization period using a timer or counter 3509 to measure the number of clock cycles or elapsed time. At the end of the initialization period, the initialization module 3508 directs the noise source 3503 to transition to an active state 3511 (transition 3512) whereby the noise source 3503 outputs a non-constant power spreading signal, such as a pseudo-random signal, a random signal, a polynomial sequence, and the like. As a result, the clock signal 3505 is modified by the now non-constant output of the noise source 3504 to produce the encoded clock signal 3506. As discussed below with reference to FIGS. 26 and 27, the receiver, in one embodiment, detects the transition 3512 of the clock signal 3506 from a unmodified clock signal to an encoded clock signal, initializes and starts its noise source, and decodes the encoded clock signal accordingly.

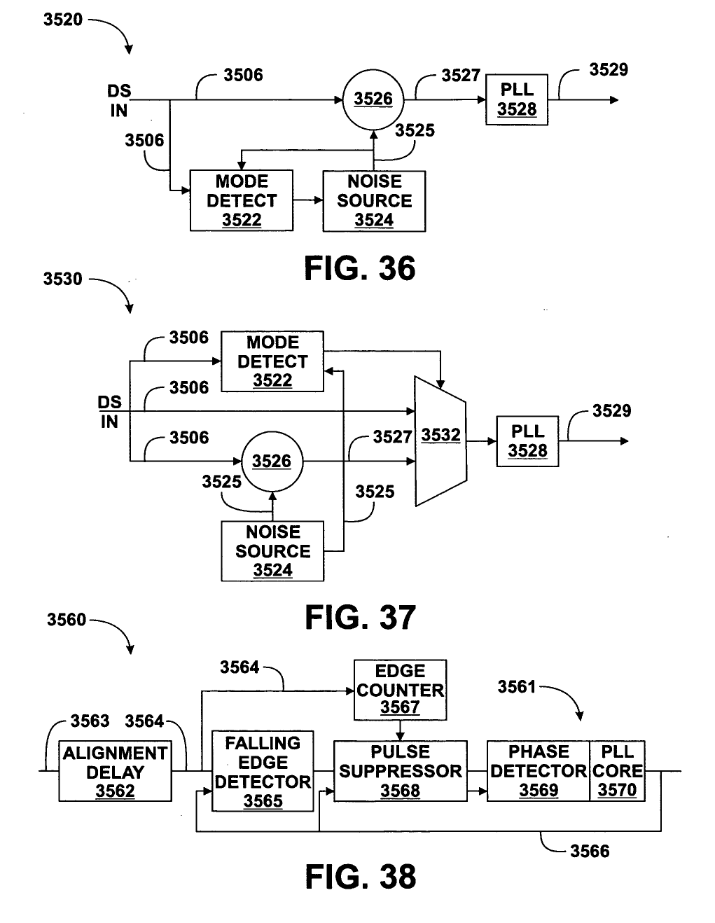

FIGS. 26 and 27 illustrate various implementations of a receiver (e.g., at the receive side of an interconnect) to detect the transition 3512 of the clock signal 3506 (FIG. 35) and synchronize a PLL accordingly. The receiver 3520 of FIG. 36 includes a mode detect module 3522 having an input to receive the clock signal 3506 via a transmission line and an output to provide control and configuration information, a noise source 3524 having an input to receive the control and configuration information and an output to provide a power spreading signal 3525, and a signal modification module 3526 having an input to receive the clock signal 3506, an input to receive the power spreading signal 3525 and an output to provide a decoded clock signal 3527. The receiver 3520 further includes a PLL 3528 having an input to receive the decoded clock signal 3527 and an output to provide a clock signal 3529 synchronized to the clock signal 3527.

In at least one embodiment, the mode detect module 3522 is operable to detect the transition 3512 of the clock signal 3506 from an unmodified clock signal to an encoded clock signal. Prior to this transition, the mode detect module 3522 may maintain the noise source 3524 in an initialization state whereby the power spreading signal 3525 is a constant logic value so that the clock signal 3506 is output in unmodified form by the signal modification module 3526 as the clock signal 3527. The PLL 3528 thereby synchronizes to the clock signal 3527, thereby effectively synchronizing to the clock signal 3506, which represents the clock signal 3502 (FIG. 35) during the initialization state. Subsequent to the transition 3512, the mode detect module 3522 may initialize the noise source 3524 and direct the noise source 3524 to enter an active state whereby a non-constant power spreading signal 3525 is output to the signal modification module 3526. As a result, the encoded clock signal 3506 is decoded using the non-constant power spreading signal 3525 to generate the clock signal 3527 which is representative of the clock signal 3502 prior to encoding during the active state.

FIG. 37 illustrates a similar receiver 3530 having the mode detect module 3522, noise source 3524, signal modification module 3526 and PLL 3528. However, rather than controlling the noise source 3524 directly, in one embodiment, the mode detect module 3522 provides a control signal to a multiplexer 3532, which has as inputs the clock signal 3506 and the clock signal 3527 and has an output coupled to the input of the PLL 3528. Based on whether the mode detect module 3522 detects that the clock signal 3506 is in normal mode or XEMI mode, the mode detector module 3522 directs the multiplexer 3532 to select one of the clock signals 3506 or 3527 for output to the PLL. When in normal mode, the clock signal 3506 represents the clock signal 3502 in unmodified form and because the noise source 3524 is not directly controlled by the mode detector module 3522 in this example, the clock signal 3527 output by the signal modification module 3526 may not represent the clock signal 3502, so the multiplexer 3532 is operated to output the clock signal 3506. Conversely, when in XEMI mode, the clock signal 3506 represents an encoded version of the clock signal 3502, whereas the clock signal 3527 represents a decoded version of the clock signal 3502, so the multiplexer is operated to provide the clock signal 3527 for output to the PLL 3528. The mode detect module 3522 may detect the transition in any of a variety of ways. For example, the mode detect module 3522 may implement a state machine whereby a specific pattern representing the transition is detected and thus indicates that the transition is occurring.

Referring to FIG. 38, a technique for maintaining a PLL lock while a transmitted clock signal transitions from normal mode to XEMI mode, or vice versa is illustrated. As noted above, the receiver typically receives an input clock signal and determines whether the input clock signal is an encoded clock signal (XCLK) or an unencoded clock signal. As discussed below, the receiver may have the ability to detect the transition from normal to encoded clock signals and start its noise source to be synchronized with the transmitter's noise source. Conversely, the receiver also may have the ability to detect the transition of the input clock signal from an encoded clock signal to an unencoded clock signal, and therefore shut down or cease utilizing its noise source to decode the input clock signal.

As illustrated in FIG. 38, a PLL synchronization module 3560 may be utilized by a decoder to identify the mode changes and adjust the PLL synchronization routine accordingly. The PLL synchronization module 3560 includes an alignment delay module 3562 having an input to receive a reference clock signal 3563 (e.g., clock signal 3527 of FIG. 36) and an output to provide a delayed clock signal 3564, a falling edge counter 3565 having two inputs to receive the delayed clock signal 3564 and a feedback signal 3566 from a PLL 3561 and an output, a pulse suppressor 3568 having an input operably coupled to the output of the falling edge counter 3565 and an output, and the PLL 3561 having a phase detector 3569 with an input operably coupled to the output of the pulse suppressor 3568 and an input to receive the feedback signal 3566 output by the PLL core 3570.

In at least one embodiment, the phase detector uses the rising edges in the reference and feedback clock signals to track the phase of the clock signal. Accordingly, the transmitter eliminates some of the redundant falling edges in the source clock and uses both the falling and rising edges in the encoded clock signal to convey phase of the clock signal. The receiver therefore reinserts the falling edges in the received signal so that the phase detector uses the correct transitions to track the phase of the remote clock source.

The alignment delay module 3562 is used to position the reference clock signal 3566 so that it can be sampled reliably by the falling edge detector 3565. The falling edge detector 3565 samples the reference clock signal 3566 to identify a missing falling edge which indicates a start of a transition between normal mode and XEMI mode. The falling edge detector 3565 may include a D-latch which captures the state of the reference clock signal 3563 on the rising edge of the feedback clock signal 3566. The missing falling edge typically would cause an edge mismatch on the inputs to the phase detector 3569 (i.e., a falling edge occurs on the reference pin when a rising edge was expected). Because the falling edges are not used by the phase detector 3569, the corresponding rising edge on the feedback clock signal 3566 would cause the phase detector 3569 to correct for the inverted rising edge, potentially causing the PLL 3561 to go out of lock. Accordingly, the pulse suppressor 3568 suppresses the rising edges on both inputs to the phase detector 3569 when the absence of a falling edge is detected by the falling edge detector 3565. In one embodiment, the rising edges are suppressed by only allowing the rising edges to occur during the high period of the sampling clock. The edge counter 3567, in one embodiment, is used to validate the mode transition signature detected by the falling edge detector 3565. The edge counter 3567 ensures that the sequence detected by the falling edge detector 3565 was not caused by errors in sampling the normal clock. The true transition sequence detected by the falling edge detector 3565 typically is the result of a reference signal which has no transitions at the nominal falling edge.

In at least one embodiment, upon power up or initialization the PLL 3561 responds to the input clock having a normal mode in a conventional manner. The PLL 3561 tracks the incoming clock and eventually generates a “lock” signal to indicate that it has achieved phase and frequency lock. The lock signal, in turn, causes a charge pump (not shown) of the PLL 3561 to limit the maximum current charge it can sink or source, thus minimizing any input frequency perturbation to the PLL output clock frequency. Thus, during a “throttling mode” the PLL 3561 does not react to as wide a phase/frequency variation in the input clock.

Conversely, when the input clock is detected as an XEMI mode and the transition to XEMI mode is complete, the lock signal is released, thereby removing the limitations on the maximum current charge used by the charge pump and therefore allowing charge pump of the PLL to act in the conventional manner. This technique helps minimize any impulse jitter when transitioning between normal clock and XEMI reduced emission clock modes.

Referring to FIG. 39, a frequency detection module 3900 for detecting a frequency change between a clock 3901 produced by a PLL and a reference clock 3902 is illustrated in accordance with at least one embodiment of the present disclosure. In the illustrated example, it is assumed that the PLL is locked to a clock signal based on the reference clock 3902, which in one embodiment is a pixel clock provided by a source device. In one embodiment, the reference clock 3902 is divided by two in a circuit (e.g., a D-flop 3911) clocked on its falling edge and the resulting output is sampled by the clock 3901 using D-flops 3912, 3913 and 3914. If a difference is detected at an XOR gate 3923 and decoding is indicated as enabled (via a decoder_enabled signal 3903), an asserted bit is inserted into a shift register comprised of D-flops 3915-22. As illustrated by FIG. 39, a detect signal 3930 is asserted when the eighth bit of the shift register is a logic one (1) an done of the first four bits in the shift register also is a logic one (1). It will be appreciated that this pattern is selected to filter out possible harmonic relationships between the clock 3901 and the reference clock 3902. In response to the assertion of the detect signal 3903, the EMI encoder/decoder 2800 can implement a reset whereby the PLL is relocked to the incoming clock reference signal.

Referring to FIG. 40, a periodic resynchronization technique is illustrated by way of a state machine diagram in accordance with at least one embodiment of the present disclosure. It will be appreciated that transient errors on the connection between the EMI encoder (on the transmit side) and the EMI decoder (on the receive side) can cause the decoder to either lose PLL lock or to lose the synchronization between the clock or data noise sources (e.g., LFSRs) in the encoder and decoder. In one embodiment, the encoder does not implement a mechanism determine that such an error has occurred. Accordingly, the encoder in this instance implements a technique referred to herein as periodic resynchronization (PR). In this process, the clock is reverted to a non-encoded clock (Normal) mode, and the data LFSR is disabled. The clock is then changed back to an encoded clock (XClk) mode and the LFSR is reinitialized, which facilitates synchronization between the encoder and decoder. Since a similar function occurs at power up or when the encoder PLL loses lock (typically due to a change in the frequency of the pixel clock), the PR state machine also handles the initialization function.

This process, in certain instances, is further involved due to the handling of two distinct situations. In the event that the decoder PLL or LFSRs are actually out of lock or sync, the encoder waits for an adequate amount of time after reverting to Normal mode to insure that the decoder PLL has locked. This is very similar to the initialization requirements on power up or when the encoder PLL loses lock.

The other situation (which will occur the majority of the time) is that the decoder PLL and LFSRs are in sync when PR occurs. In this case it is required that no disruption occur in the data stream being sent to the sink by the decoder. Handling this requires careful synchronization of all LFSR changes. Accordingly, the PR process should occur frequently enough that the maximum duration of an erroneous situation is reduced or minimized. However, EMI is increased because the system spends some time out of XClk mode on each PR. For purposes of the following discussion, it is assumed that a PR operation is performed once every sixteen vertical frames of video content transmitted over the interconnect, which typically is on the order of ¼ to ½ second, thereby typically resulting in minimal impact on EMI performance.

FIG. 40 illustrates the state machine for Periodic Resynchronization and Initialization which can be implemented by the EMI controller 2803 (FIG. 28). For initialization, whenever a power on reset (POR) is asserted or a PLL lock indicator from the PLL is deasserted or if the three DVI/HDMI data channels are not aligned (indicated by the FIFO_ALIGNED signal, FIG. 26), the state machine enters state 4005. In this state, the clock encoder is forced to Normal mode by the deassertion, a training sequence represented by the bit sequence 1010101010 is forced onto the data outputs, and a counter CTR is preset to 131,072 (indicated by the notation INITCTR). In one embodiment, rather than being a request, this Normal mode switch is a forced switch.

Once the POR signal has been deasserted, the PLL is locked and the data channels are aligned, the state machine goes to state 4006. In addition, the transmit side waits to receive eight rising edges on the VSYNC_DET signal 2307 (FIGS. 23 and 24), indicating that eight frames or a minimum of 3,000,000 training patterns have been sent. At state 4006, the CTR is decremented on for each cycle of the pixel clock. When the counter CTR reaches 0, a delay of at least ˜500 microseconds has elapsed (assuming a pixel clock frequency of 250 MHz or less), thereby providing sufficient time for the PLL and all of the DLLs in the receiver to lock. At this point the state machine proceeds to state 4003.

At state 4003, the state machine waits until the start of a Display Period (indicated by the notation DE and signaled by the DE input from channel 0 making a low to high transition with the CTL decode from channels 1 and 2 on the previous cycle not equal to the data preamble value 0101). At this point, the state machine enters state 4004 and initialize a counter to count VSYNC edges. The state machine then proceeds to state 4000.

In state 4000, clock encoding is enabled for the transmitter and rising edges of the VSYNC_DET signal 2307 are counted. As the polarity of VSYNC typically is not known, it can be either the leading or trailing edge. Once sixteen edges have been detected, thereby indicating sixteen display frames have been transmitted, the state machine transitions to state 4001, at which point clock encoding is disabled, the delay counter is initialized to 131,072 and the state machine then enters state 4002. Note that the edges of VSYNC_DET signal 2307 occur in the vertical blanking period, and the maximum number of cycles that can occur before the clock actually switches is about 560, thereby causing state 4001 to occur at a blanking interval. At state 4002, the counter CTR until it reaches zero, at which point state 4003 is entered and the sequence is repeated.

If the decoder PLL was unlocked when the PR was initiated, it will have already changed the decoder to from XClk mode to Normal mode. The 131,072 cycle count at state 4002 allows the decoder PLL to relock to the Normal mode clocks before switching back to XClk mode. If the decoder is in sync, the transitions between XClk and Normal modes will be synchronized between the encoder and decoder.

After the 131,072 cycle count in state 4002, both state machines go to state 4003. Since this is triggered from an edge of VSYNC which is identical in both the transmitter and receiver, it occurs on the same pixel clock in each device, although at a random point relative to the Video Display period. At the start of the next Video Display period the transmitter machine goes to state 4004 and then to 4000. The result is that the signal enabling the encoder and the signal enabling the decoder change states on exactly the same pixel clock cycle at both sides, thus ensuring that the encode and decode LFSRs remain synchronized.

In a first aspect, an apparatus can include a plurality of conductive interconnects, and a first cable receptacle including a first housing. The apparatus can also include a first receptacle interface coupleable to an interface of a first device, and first active signal management circuitry disposed within the first housing, the first active signal management circuitry coupled to the first receptacle interface to receive a first digital signal from the interface of the first device and coupled to a first conductive interconnect of the plurality of conductive interconnects, the first active signal management circuitry configured to provide a second digital signal, based on the first digital signal, to the first conductive interconnect.

In one embodiment of the first aspect, the first active signal management circuitry includes an integrated circuit. In another embodiment, the first cable receptacle includes one of: a Digital Video Interface (DVI) compatible cable receptacle; a High Definition Multimedia Interface (HDMI) compatible cable receptacle; a DisplayPort compatible cable receptacle; a Universal Display Interface (UDI) compatible cable receptacle; a Universal Serial Bus (USB) compatible cable receptacle; and a FireWire compatible cable receptacle. In a further embodiment, the apparatus includes a cable. In still another embodiment, the apparatus includes a cable adaptor.

In still a further embodiment of the first aspect, the first digital signal includes a quasi differential signal, and the second digital signal includes a true differential signal. The first active signal management circuitry includes a true differential transmitter configured to provide the second digital signal. In a particular embodiment, the first active signal management circuitry includes a quasi differential signal receiver configured to receive the first digital signal.

In still another embodiment of the first aspect, the first digital signal includes a true differential signal, and the second digital signal includes a quasi differential signal. The first active signal management circuitry includes a true differential signal configured to receive the first digital signal, and a quasi differential transmitter configured to provide the second digital signal. In another further embodiment, the first active signal management circuitry includes a quasi differential signal receiver configured to receive the first digital signal, and a quasi differential signal transmitter configured to provide the second digital signal.

In another embodiment of the first aspect, the first active signal management circuitry includes a true differential signal receiver configured to receive the first digital signal, and a true differential signal transmitter configured to provide the second digital signal. In still another embodiment, the first active signal management circuitry includes a noise source configured to provide a digital noise signal, and a modification module configured to modify an input digital signal based on the digital noise signal to generate a modified digital signal, wherein the input digital signal is based on the first digital signal and the second digital signal is based on the modified digital signal.

In an even further embodiment, the first active signal management circuitry includes a symbol encoder configured to encode at least one occurrence of a substantially periodic data symbol of an input digital signal to generate a symbol-encoded digital signal, wherein the input digital signal is based on the first digital signal and the second digital signal is based on the symbol-encoded digital signal. In a more particular embodiment, the first digital signal includes a video signal and the substantially periodic data symbol includes one of: a synch control symbol, and a substantially periodic video data symbol.

In yet another embodiment of the first aspect, the first active signal management circuitry includes a deserializer configured to generate a first plurality of parallel digital signals based on an input serialized digital signal, wherein the input serialized digital signal is based on the first digital signal. The apparatus can also include a serializer configured to generate an output serialized digital signal based on a second plurality of parallel digital signals, wherein the second plurality of parallel digital signals is based on the first plurality of parallel digital signals and wherein the second digital signal is based on the output serialized digital signal. In an even more particular embodiment, an encoder/decoder configured to generate at least a subset of the second plurality of parallel digital signals based on at least a subset of the first plurality of parallel digital signals.

In another particular embodiment, the encoder/decoder includes at least one of an electromagnetic interference (EMI) encoder, an EMI decoder, a period symbol encoder, a periodic symbol decoder, an encryption module, and a decryption module. In a further embodiment of the first aspect, the first active signal management circuitry includes an encryption module configured to encrypt an input digital signal to generate an encrypted digital signal, wherein the input signal is based on the first digital signal and the second digital signal is based on the encrypted digital signal.

In still another embodiment, the first active signal management circuitry includes a decryption module configured to decrypt an encrypted digital signal to generate a decrypted digital signal, wherein the encrypted signal is based on the first digital signal and the second digital signal is based on the decrypted digital signal. In an even further embodiment, the first active signal management circuitry includes a bit alignment module configured to detect a data symbol alignment of the first digital signal.

In a still further embodiment, the first active signal management circuitry is coupled to the first receptacle interface to receive a third digital signal from the interface of the first device and is coupled to a second conductive interconnect of the cable body to provide a fourth digital signal, based on the third digital signal, to the second conductive path. The first active signal management circuitry includes a first shift register having an input to shift in bits of the first digital signal and an output to provide a first N bit data symbol, a second shift register having an input to shift in bits of the second digital signal and an output to provide a second N bit data symbol, a first buffer to store the first N bit data symbol, a second buffer to store the second N bit data symbol, and control circuitry to output the first N bit data symbol from the first buffer and to output the second N bit data symbol from the second buffer substantially concurrently in response to an indication that the first N bit data symbol has been stored in the first buffer and that the second N bit data symbol has been stored in the second buffer.

In another embodiment of the first aspect, a second cable receptacle includes a second housing, a second receptacle interface coupleable to an interface of a second device, and second active signal management circuitry disposed within the second housing, the second active signal management circuitry coupled to the first conductive interconnect to receive the second digital signal and coupled to the second receptacle interface, the second active signal management circuitry configured to provide a third digital signal, based on the second digital signal, to the second receptacle interface. In an even more particular embodiment, the second digital signal includes a true differential signal, the third digital signal includes a quasi differential signal, and the second active signal management circuitry includes a quasi differential signal transmitter to provide the third digital signal.

In a further particular embodiment, the first active signal management circuitry includes a true differential signal driver to provide the second digital signal. In an even further particular embodiment, the first active signal management circuitry includes a first integrated circuit and the second active signal management circuitry includes a second integrated circuit. In still a further particular embodiment, the apparatus includes one of a cable and a cable adaptor.

In a second aspect, an apparatus can include a first bidirectional port, a second bidirectional port, and active signal management circuitry having an input to receive an input digital signal and an output to provide an output digital signal, wherein the active signal management circuitry is configured to generate the output digital signal based on the input digital signal. The apparatus can also include a first transceiver includes a first input and a first output coupled to the first bidirectional port, a second input selectively coupleable to the output of the active signal management circuitry, and a second output selectively coupleable to the input of the active signal management circuitry and a second transceiver includes a first input and a first output coupled to the second bidirectional port, a second input selectively coupleable to the output of the active signal management circuitry, and a second output selectively coupleable to the input of the active signal management circuitry. The apparatus can further include a switch component configured to couple the second output of the first transceiver to the input of the active signal management circuitry and couple the output of the active signal management circuitry to the second input of the second transceiver in response to a first direction signal having a first state, and couple the second output of the second transceiver to the input of the active signal management circuitry and couple the output of the active signal management circuitry to the second input of the second transceiver in response to a first direction signal having a second state.

In a third aspect, a cable apparatus can include a plurality of conductive interconnects a first cable receptacle includes a first receptacle interface coupleable to an interface of a first device, and a second cable receptacle includes a second receptacle interface coupleable to an interface of a second device. The apparatus can also include a first bidirectional circuit component disposed at the first cable receptacle and having a first port connected to a pin interface of the first cable receptacle and a second port coupled to a first conductive interconnect of the plurality of conductive interconnects. The first bidirectional circuit component can include first active signal management circuitry includes an input to receive a first input digital signal and an output to provide a first output digital signal, the first active signal management circuitry configured to generate the first output signal based on the first input digital signal, and a first switching component configured to selectively couple one of the input or the output of the first active signal management circuitry to the first port and selectively couple the other of the input or the output of the first active signal management circuitry to the second port based on a state of a first direction signal.

In a fourth aspect, a cable apparatus can include a first cable receptacle including a first receptacle interface coupled to an interface of a first device, a second cable receptacle includes a second receptacle interface coupleable to an interface of a second device, first active signal management circuitry disposed at the first cable receptacle and having a first port connected to a pin interface of the first cable receptacle and a second port coupled to a conductive interconnect, and second active signal management circuitry disposed at the second cable receptacle and having a third port connected to a pin interface of the second cable receptacle and a fourth port coupled to the conductive interconnect. The method can include determining which one of the first device or the second device includes a transmitting device, in response to determining that the first device includes the transmitting device, and configuring the first active signal management circuitry to receive a first digital signal at the first port and provide a second digital signal to the second port. The method can further include performing, at the first active signal management circuitry, a first active signal management process based on the first digital signal to generate the second digital signal, and configuring the second active signal management circuitry to receive the second digital signal at the fourth port and provide a third digital signal to the third port, and performing, at the second active signal management circuitry, a second active signal management process based on the second digital signal to generate the third digital signal.

In a fifth aspect, an apparatus can include a first integrated circuit including a first port, a second port, a quasi differential signal receiver including an input coupled to the first port and configured to receive a first quasi differential signal representative of a first data, and a true differential signal transmitter including an output coupled to the second port and configured to provide a first true differential signal representative of the first data.

In a sixth aspect, a method can include receiving, at a first cable receptacle of a cable apparatus, a first quasi differential signal from a first device, the first quasi differential signal representative of a data, and transmitting a first true differential signal representative for reception by a second cable receptacle of the cable apparatus, the first true differential signal representative of the data.

In a seventh aspect, an apparatus can include an integrated circuit including a first port, a second port, a true differential signal receiver including an input coupled to the first port and configured to receive a true differential signal representative of a data, and a quasi differential signal transmitter including an output coupled to the second port and configured to provide a quasi differential signal representative of the data.

In an eighth aspect, a method can include receiving, at a first cable receptacle of a cable apparatus, a true differential signal representative of a data from a second cable receptacle of the cable apparatus, and transmitting a quasi differential signal representative of the data for reception by a device.

In a ninth aspect, a method can include receiving a plurality of digital signals, for each digital signal of the plurality of digital signals, bit shifting the digital signal into a shift register of the integrated circuit to determine a data symbol of the digital signal, and buffering the data symbol in one of a plurality of buffers corresponding to the digital signal. The method can also include configuring one of a plurality of buffer signals corresponding to the digital signal to have a first state in response to buffering the data symbol, and concurrently accessing the data symbol from each of the plurality of buffers in response to each of the buffer signals of the plurality of buffer signals having the first state.

In a tenth aspect, an apparatus can include a first plurality of ports, each port configured to receive a corresponding digital signal of a first plurality of digital signals, and a plurality of bit shift registers, each bit shift register including an input coupled to a corresponding one of the first plurality of ports and an output configured to provide a data symbol of the corresponding digital signal of the first plurality of digital signals. The apparatus can also include a plurality of buffers, each buffer including a first input coupled to the output of a corresponding one of the plurality of bit shift registers, a second input configured to receive an alignment signal, a first output configured to provide a buffering signal, and a second output configured to provide a buffered data symbol in response to the alignment signal indicating an aligned state, wherein each buffer is configured to configure the corresponding buffering signal to indicate a data buffered state in response to buffering the data symbol from the corresponding bit shift register. The apparatus can further include an alignment controller including a plurality of inputs, each input coupled to the first output of a corresponding one of the plurality of buffers to receive the corresponding buffering signal, and an output configured to configure the alignment signal to indicate the aligned state in response to each buffering signal for each of the plurality of buffers indicating the data buffered state.

In an eleventh aspect, an apparatus can include a plurality of conductive interconnects, and a first cable receptacle including a first housing, a first receptacle interface coupleable to an interface of a first device, a deserializer configured to generate a first plurality of parallel digital signals based on an input serialized digital signal, and a serializer configured to generate an output serialized digital signal based on a second plurality of parallel digital signals, wherein the second plurality of parallel digital signals is based on the first plurality of parallel digital signals.

In a twelfth aspect, a method can include receiving, at a cable receptacle of a cable assembly, a first serialized digital signal, deserializing, at the cable receptacle, the first serialized digital signal to generate a first plurality of parallel digital signals, and serializing, at the cable receptacle, a second plurality of parallel digital signals to generate a second serialized digital signal, wherein the second plurality of parallel digital signals is based on the first set of parallel digital signals.

In a thirteenth aspect, an apparatus can include a transition minimized differential signaling (TMDS) decoder includes an input configured to receive a first TMDS encoded signal and an output configured to provide a first TMDS decoded signal based on the first TMDS encoded signal. The apparatus can also include an electromagnetic interference (EMI) encoder/decoder includes an input configured to receive the first TMDS decoded signal and an output configured to provide a second TMDS decoded signal, wherein the EMI encoder is configured to generate the second TMDS decoded signal based on the first TMDS decoded signal and a digital noise signal, and a TMDS encoder includes an input configured to receive the second TMDS decoded signal and an output configured to provide a second TMDS encoded signal based on the second TMDS decoded signal.

In a fourteenth aspect, a method can include receiving a first transition minimized digital signaling (TMDS) encoded signal, decoding the first TMDS encoded signal to generate a first TMDS decoded signal, modifying the first TMDS decoded signal based on a digital noise signal to generate a second TMDS decoded signal, and encoding the second TMDS decoded signal to generate a second TMDS encoded signal.

In a fifthteenth aspect, a cable apparatus can include a first cable receptacle including a first receptacle interface couplable to an interface of a first device, and a first port configured to receive a first transitional minimized differential signal (TMDS) encoded digital signal, a second port configured to provide a second TMDS encoded signal based on the first TMDS encoded digital signal. The apparatus can also include a first TMDS decoder includes an input configured to receive a third TMDS encoded signal and an output configured to provide a first TMDS decoded signal based on the third TMDS encoded signal, wherein the third TMDS encoded signal is based on the first TMDS encoded signal, and a first EMI encoder includes an input configured to receive the first TMDS decoded signal and an output configured to provide a second TMDS decoded signal, wherein the first EMI encoder is configured to generate the second TMDS decoded signal based on the first TMDS decoded signal and a first digital noise signal. The apparatus can further include a first TMDS encoder including an input configured to receive the second TMDS decoded signal and an output configured to provide a fourth TMDS encoded signal based on the second TMDS decoded signal, wherein the second TMDS encoded signal is based on the fourth TMDS encoded signal.

Other embodiments, uses, and advantages of the disclosure will be apparent to those skilled in the art from consideration of the specification and practice of the disclosure disclosed herein. The specification and drawings should be considered only, and the scope of the disclosure is accordingly intended to be limited only by the following claims and equivalents thereof.

What is claimed is:

1. An apparatus comprising:
a first integrated circuit comprising:
a first port;
a second port;
a quasi differential signal receiver comprising an input coupled to the first port and configured to receive a first quasi differential signal representative of a first data; and
a true differential signal transmitter comprising an output coupled to the second port and configured to provide a first true differential signal representative of the first data.

2. The apparatus of claim 1, wherein the integrated circuit further comprises:
a true differential signal receiver comprising an input coupled to the second port and configured to receive a second true differential signal representative of a second data; and
a quasi differential signal transmitter comprising an output coupled to the second port and configured to provide a second quasi differential signal representative of the second data.

3. The apparatus of claim 2, wherein:
the quasi differential signal receiver comprises a current mode logic (CML) receiver;
the quasi differential signal transmitter comprises a CML transmitter;
the true differential signal transmitter comprises a low voltage differential signaling (LVDS) transmitter; and
the true differential signal receiver comprises a LVDS receiver.

4. The apparatus of claim 2, wherein:
the true differential signal transmitter is configured to provide at least one of signal preemphasis and signal deemphasis.

5. The apparatus of claim 2, wherein the true differential signal receiver is configured to provide signal equalization.

6. The apparatus of claim 1, wherein the quasi differential signal receiver comprises a current mode logic (CML) receiver.

7. The apparatus of claim 1, wherein the true differential signal transmitter comprises a low voltage differential signaling (LVDS) transmitter.

8. The apparatus of claim 1, wherein the quasi differential signal receiver comprises at least one of: a peripheral component interconnect (PCI) Express compatible receiver; a Universal Serial Bus (USB) compatible receiver, a Firewire compatible receiver, and a Serial AT Attachment (SATA) compatible receiver.

9. The apparatus of claim 1, further comprising:
paired conductive interconnects, wherein the second port is coupled to the paired conductive interconnects; and
a second integrated circuit comprising:
a third port coupled to the paired conductive interconnects;
a fourth port;
a true differential signal receiver comprising an input coupled to the third port and configured to receive the first quasi differential signal; and
a quasi differential signal transmitter comprising an output coupled to the fourth port and configured to provide a second true differential signal representative of the first data.

10. The apparatus of claim 9, wherein the apparatus comprises a cable apparatus comprising:
a first cable receptacle comprising the first integrated circuit; and
a second cable receptacle comprising the second integrated circuit.

11. The apparatus of claim 10, wherein the cable apparatus comprises a cable.

12. The apparatus of claim 10, wherein the cable apparatus comprises a cable adaptor.

13. The apparatus of claim 1, wherein the first quasi differential signal comprises a video signal.

14. A method comprising:
receiving, at a first cable receptacle of a cable apparatus, a first quasi differential signal from a first device, the first quasi differential signal representative of a data; and
transmitting a first true differential signal representative for reception by a second cable receptacle of the cable apparatus, the first true differential signal representative of the data.

15. The method of claim 14, further comprising:
receiving, at the second cable receptacle, the first true differential signal; and
transmitting a second quasi differential signal representative of the first data for reception by a second device, the second quasi differential signal representative of the data.

16. The method of claim 15, wherein the first device comprises a video source device and the second device comprises a video display device.

17. The method of claim 15, further comprising:
performing, at the first cable receptacle, a first active signal management process for a first digital signal representative of the data to generate a second digital signal, wherein the first true differential signal is based on the second digital signal; and
performing, at the second cable receptacle, a second active signal management process for a third digital signal representative of the data to generate a fourth digital signal, wherein the second quasi differential signal is based on the fourth digital signal.

18. The method of claim 14, further comprising:
performing, at the first cable receptacle, an active signal management process for a first digital signal representative of the data to generate a second digital signal, wherein the first true differential signal is based on the second digital signal.

19. An apparatus comprising:
an integrated circuit comprising:
a first port;
a second port;
a true differential signal receiver comprising an input coupled to the first port and configured to receive a true differential signal representative of a data; and
a quasi differential signal transmitter comprising an output coupled to the second port and configured to provide a quasi differential signal representative of the data.

20. The apparatus of claim 19, wherein the quasi differential signal transmitter comprises a current mode logic (CML) transmitter.

21. The apparatus of claim 19, wherein the true differential signal receiver comprises a low voltage differential signaling (LVDS) receiver.

22. The apparatus of claim 21, wherein the apparatus comprises a cable apparatus comprising:
paired conductive interconnects, wherein the first port is coupled to the paired conductive interconnects; and
a cable receptacle comprising the integrated circuit.

23. The apparatus of claim 21, wherein the true differential signal comprises a video signal.

24. A method comprising:
receiving, at a first cable receptacle of a cable apparatus, a true differential signal representative of a data from a second cable receptacle of the cable apparatus; and
transmitting a quasi differential signal representative of the data for reception by a device.

25. The method of claim 24, wherein the device comprises a video display device.

26. The method of claim 24, further comprising:
performing, at the first cable receptacle, an active signal management process for a first digital signal representative of the data to generate a second digital signal, wherein the quasi differential signal is based on the second digital signal.
